(19) United States
(12) Patent Application Publication
(10) Pub. No.: US 2025/0180791 A1
(43) Pub. Date: Jun. 5, 2025

(54) OPTICAL FILTER

(71) Applicant: AGC Inc., Tokyo (JP)

(72) Inventors: Yuichiro ORITA, Fukushima (JP); Kazuhiko SHIONO, Fukushima (JP); Takashi NAGATA, Shizuoka (JP); Takahiro SAKAGAMI, Shizuoka (JP)

(73) Assignee: AGC Inc., Tokyo (JP)

(21) Appl. No.: 19/048,086

(22) Filed: Feb. 7, 2025

Related U.S. Application Data
(63) Continuation of application No. PCT/JP2023/030941, filed on Aug. 28, 2023.

(30) Foreign Application Priority Data
Aug. 31, 2022 (JP) 2022-138362

(51) Int. Cl. G02B 5/20; C08K 5/00; C08L 33/26; G02B 1/04; G02B 1/115; H10F 39/00

(52) U.S. Cl. CPC G02B 5/208; C08K 5/0041; C08L 33/26; G02B 1/04; G02B 1/115; H10F 39/8057

(57) ABSTRACT

An optical filter includes: a substrate, an antireflection layer 1 including a dielectric multilayer film laminated on one main surface side of the substrate, and an antireflection layer 2 including a dielectric multilayer film laminated on the other main surface side of the substrate. The substrate includes a near-infrared ray absorbing glass and a resin film, the resin film includes a resin, a UV dye having a maximum absorption wavelength in 350 nm to 410 nm in the resin, and an IR dye having a maximum absorption wavelength in 700 nm to 850 nm in the resin, and the optical filter satisfies all of the characteristics (i-1) to (i-7).

### CROSS-REFERENCE TO RELATED APPLICATIONS

This is a bypass continuation of International Application No. PCT/JP2023/030941 filed on Aug. 28, 2023, and claims priority from Japanese Patent Application No. 2022-138362 filed on Aug. 31, 2022, the entire content of which is incorporated herein by reference.

### TECHNICAL FIELD

The present invention relates to an optical filter that transmits visible light and shields near-infrared light.

### BACKGROUND ART

In an imaging device including a solid state image sensor, in order to satisfactorily reproduce a color tone and obtain a clear image, an optical filter that transmits light in a visible region (hereinafter, also referred to as “visible light”) and shields light in an ultraviolet wavelength region (hereinafter, also referred to as “ultraviolet light”) and light in a near-infrared wavelength region (hereinafter, also referred to as “near-infrared light”) is used.

As the optical filter, for example, a reflection type filter is known in which interference of light is used by a dielectric multilayer film in which dielectric thin films having different refractive indices are alternately laminated on one surface or both surfaces of a transparent substrate, and light desired to be shielded is reflected. In such an optical filter, since an optical film thickness of the dielectric multilayer film changes depending on an incident angle of light, there is a problem that a spectral transmittance curve and a spectral reflectance curve change depending on the incident angle. For example, according to the number of laminated layers of the multilayer film, a large change in transmittance in a visible light region due to interference caused by reflected light at interfaces of respective layers, that is, a ripple is generated, and the larger the incident angle of light is, the stronger the generation of the ripple is. This causes a problem in that a captured amount of light in a visible light region changes at a high incident angle and image reproducibility is reduced.

When light is incident at a high incident angle, a light leakage may occur in which near-ultraviolet light that should have a high reflectance is transmitted. Since an image sensor has sensitivity also in a near-ultraviolet light region, when light-shielding properties of the near-ultraviolet light are not sufficient, a reduction in image quality due to unnecessary light called flare or ghost may occur in an acquired visible light image.

As described above, with a reduction in height of camera modules in recent years, use under a condition of a high incident angle is assumed, and therefore an optical filter that is less likely to be affected by an incident angle is required.

Patent Literature 1 discloses an optical filter having both a near-ultraviolet light cutting ability and a near-infrared light cutting ability, in which a copper phosphonate film is formed on a glass substrate.

Patent Literature 2 discloses an optical filter having both a near-ultraviolet light cutting ability and a near-infrared light cutting ability, which includes an absorbing layer containing a near-ultraviolet light absorbing dye and a near-infrared light absorbing dye in a transparent resin and a copper phosphonate film.

Patent Literature 3 discloses an optical filter having both a near-ultraviolet light cutting ability and a near-infrared light cutting ability, which includes an absorbing layer containing a near-ultraviolet light absorbing dye and a near-infrared light absorbing dye in a transparent resin.

### CITATION LIST

### Patent Literature

### Patent Literature 1: JP6232161B

### Patent Literature 2: JP6966334B

### Patent Literature 3: JP6939224B

### SUMMARY OF INVENTION

### Technical Problem

However, in the optical filter disclosed in Patent Literature 1, there is room for improvement in terms of light-shielding properties in a near-ultraviolet region, particularly in the vicinity of a wavelength of 400 nm.

In the optical filter disclosed in Patent Literature 2, there is room for improvement in terms of light-shielding properties in a near-ultraviolet region, particularly in the vicinity of a wavelength of 400 nm, and a change in transmittance between a light-shielding region of ultraviolet light and a transmission region of visible light is gentle, so there is also room for improvement in terms of achieving both light-shielding properties and transmittance.

In the optical filter disclosed in Patent Literature 3, since light-shielding properties are ensured only by the near-ultraviolet light absorbing dye and the near-infrared light absorbing dye, those dyes need to be used in a large amount, and there is a concern that the transmittance of visible light may be reduced.

An object of the present invention is to provide an optical filter in which a ripple in a visible light region is prevented even at a high incident angle, and has excellent shielding properties of near-infrared light and near-ultraviolet light while maintaining a high transmittance of visible light, particularly excellent shielding properties of ultraviolet light in the vicinity of a wavelength of 400 nm.

### Solution to Problem

The present invention provides an optical filter having the following configuration.

[1] An optical filter including: a substrate, an antireflection layer 1 including a dielectric multilayer film laminated as an outermost layer on one main surface side of the substrate, and an antireflection layer 2 including a dielectric multilayer film laminated as an outermost layer on the other main surface side of the substrate,
in which the substrate includes a near-infrared ray absorbing glass and a resin film laminated on at least one main surface of the near-infrared ray absorbing glass,
the resin film includes a resin, a UV dye having a maximum absorption wavelength in 350 nm to 410 nm in the resin, and an IR dye having a maximum absorption wavelength in 700 nm to 850 nm in the resin, and
the optical filter satisfies all of the following spectral characteristics (i-1) to (i-7):
(i-1) in a spectral transmittance curve at an incident angle of 0 degrees, an average transmittance T_{350-390(0deg)AVE} at a wavelength of 350 nm to 390 nm is 1% or less
(i-2) in a spectral transmittance curve at an incident angle of 0 degrees, a transmittance T_{400(0deg)} at a wavelength of 400 nm is 3% or less
(i-3) in a spectral transmittance curve at an incident angle of 0 degrees, a transmittance T_{400(0deg)} at a wavelength of 400 nm and a transmittance T_{430(0deg)} at a wavelength of 430 nm satisfy the following relation:

$${T}_{430 ( 0 deg )} - {T}_{400 ( 0 deg )} \geq 78 \%$$

(i-4) in a spectral transmittance curve at an incident angle of 0 degrees, an average transmittance T_{430-600(0deg)AVE} at a wavelength of 430 nm to 600 nm is 80% or more
(i-5) when an antireflection layer 1 side is set as an incident direction, an absolute value of a difference between an average reflectance R1_{430-600(5deg)AVE} at a wavelength of 430 nm to 600 nm in a spectral reflectance curve at an incident angle of 5 degrees and an average reflectance R1_{430-600(50deg)AVE} at a wavelength of 430 nm to 600 nm in a spectral reflectance curve at an incident angle of 50 degrees is 4% or less
(i-6) when an antireflection layer 2 side is set as an incident direction, an absolute value of a difference between an average reflectance R2_{430-600(5deg)AVE} at a wavelength of 430 nm to 600 nm in a spectral reflectance curve at an incident angle of 5 degrees and an average reflectance R2_{430-600(50deg)AVE} at a wavelength of 430 nm to 600 nm in a spectral reflectance curve at an incident angle of 50 degrees is 4% or less
(i-7) in a spectral transmittance curve at an incident angle of 0 degrees, an average transmittance T_{750-1100(0deg)AVE} at a wavelength of 750 nm to 1,100 nm is 2% or less.

### Advantageous Effects of Invention

According to the present invention, it is possible to provide an optical filter in which a ripple in a visible light region is prevented even at a high incident angle, and has excellent shielding properties of near-infrared light and near-ultraviolet light while maintaining a high transmittance of visible light, particularly excellent shielding properties of ultraviolet light in the vicinity of a wavelength of 400 nm, and an imaging device including the above optical filter.

### BRIEF DESCRIPTION OF DRAWINGS

FIG. 1 is a cross-sectional view schematically illustrating an example of an optical filter according to the present embodiment.

FIG. 2 is a diagram illustrating a spectral transmittance curve of a phosphate glass.

FIG. 3 is a diagram illustrating spectral transmittance curves of an optical filter of Example 1-1.

FIG. 4 is a diagram illustrating spectral reflectance curves (A surface side) of the optical filter of Example 1-1.

FIG. 5 is a diagram illustrating spectral reflectance curves (B surface side) of the optical filter of Example 1-1.

FIG. 6 is a diagram illustrating spectral transmittance curves of an optical filter of Example 1-7.

FIG. 7 is a diagram illustrating spectral reflectance curves (A surface side) of the optical filter of Example 1-7.

FIG. 8 is a diagram illustrating spectral reflectance curves (B surface side) of the optical filter of Example 1-7.

FIG. 9 is a diagram illustrating spectral transmittance curves of an optical filter of Example 1-8.

FIG. 10 is a diagram illustrating spectral reflectance curves (A surface side) of the optical filter of Example 1-8.

FIG. 11 is a diagram illustrating spectral reflectance curves (B surface side) of the optical filter of Example 1-8.

### DESCRIPTION OF EMBODIMENTS

Hereinafter, embodiments of the present invention are described.

In the present description, a near-infrared ray absorbing dye may be abbreviated as an “TR dye”, and an ultraviolet absorbing dye may be abbreviated as a “UV dye”.

In the present description, a compound represented by a formula (I) is referred to as a compound (I). The same applies to compounds represented by other formulae. A dye composed of the compound (I) is also referred to as a dye (I), and the same applies to other dyes. A group represented by the formula (I) is also referred to as a group (I), and the same applies to groups represented by other formulae.

In the present description, an internal transmittance is a transmittance obtained by subtracting an influence of interface reflection from a measured transmittance, which is represented by a formula of {measured transmittance (incident angle of 0 degrees)/(100−reflectance (incident angle of 5 degrees))}×100.

In the present description, an absorbance is converted from an (internal) transmittance by a formula of −log 10((internal) transmittance/100).

In the present description, spectra of a transmittance of a substrate and a transmittance of a resin film including a case where a dye is contained in a resin are all “internal transmittance” even when described as a “transmittance”. On the other hand, a transmittance of an optical filter including the dielectric multilayer film are measured transmittances.

In the present description, a transmittance of, for example, 90% or more in a specific wavelength region means that the transmittance does not fall below 90% in the entire wavelength region, that is, a minimum transmittance in the wavelength region is 90% or more. Similarly, a transmittance of, for example, 1% or less in a specific wavelength region means that the transmittance does not exceed 1% in the entire wavelength region, that is, a maximum transmittance in the wavelength region is 1% or less. The same applies to the internal transmittance. An average transmittance and an average internal transmittance in the specific wavelength region are the arithmetic mean of a transmittance and an internal transmittance per 1 nm in the wavelength region.

Spectral characteristics can be measured by using an ultraviolet-visible-near-infrared spectrophotometer.

In the present description, the word “to” that is used to express a numerical range includes upper and lower limits of the range.

### <Optical Filter>

An optical filter (hereinafter, also referred to as “the filter”) according to one embodiment of the present invention includes a substrate, an antireflection layer 1 formed of a dielectric multilayer film laminated as an outermost layer on one main surface side of the substrate, and an antireflection layer 2 formed of a dielectric multilayer film laminated as an outermost layer on the other main surface side of the substrate.

The substrate includes a near-infrared ray absorbing glass and a resin film laminated on at least one main surface of the near-infrared ray absorbing glass. The resin film contains a resin, a UV dye having a maximum absorption wavelength in 350 nm to 410 nm in the resin, and an IR dye having a maximum absorption wavelength of 700 nm to 850 nm in the resin. In the present invention, since the dielectric multilayer film is an antireflection layer, reflection characteristics are small, and light-shielding properties of the optical filter is substantially ensured by absorption characteristics of the near-infrared ray absorbing glass, the JR dye, and the UV dye. Since the absorption characteristics are not affected by the incident angle of light, the optical filter as a whole can achieve an excellent transmittance in the visible light region and excellent shielding properties in the near-infrared light region and the near-ultraviolet light region while preventing a ripple in the visible light region.

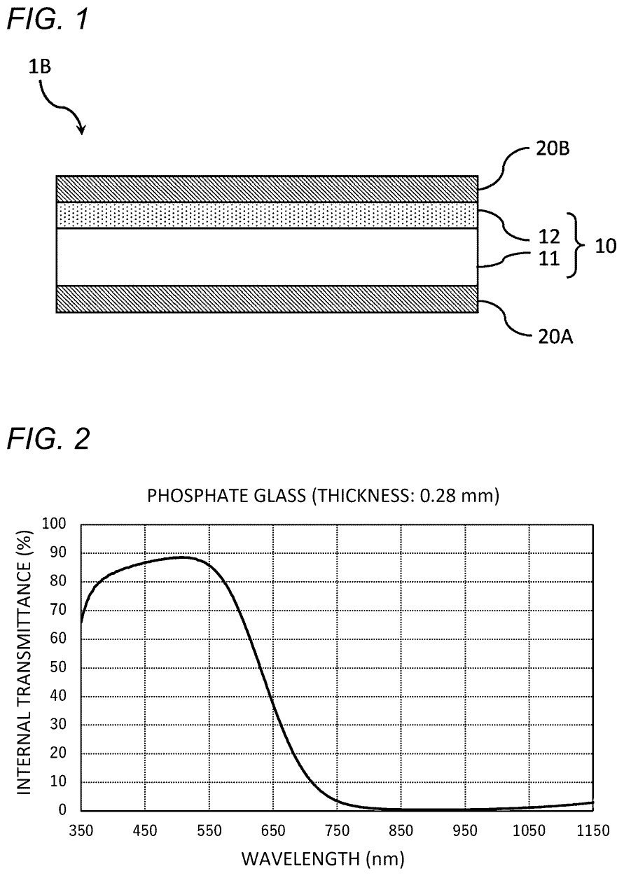

A configuration example of the filter is described with reference to the drawings. FIG. 1 is a cross-sectional view schematically illustrating an example of the optical filter according to one embodiment.

An optical filter 1B illustrated in FIG. 1 is an example in which a dielectric multilayer film 20A is provided on a main surface side of a substrate 10 including a near-infrared ray absorbing glass 11 and a resin film 12, and a dielectric multilayer film 20B is provided on the other main surface side thereof. Note that “including a specific layer on a main surface of a substrate” is not limited to a case where the layer is provided in contact with the main surface of the substrate, and includes a case where another functional layer is provided between the substrate and the layer.

The optical filter according to the present embodiment satisfies all of the following spectral characteristics (i-1) to (i-7).
(i-1) In a spectral transmittance curve at an incident angle of 0 degrees, an average transmittance T_{350-390(0deg)AVE} at a wavelength of 350 nm to 390 nm is 1% or less.
(i-2) In a spectral transmittance curve at an incident angle of 0 degrees, a transmittance T_{400(0deg)} at a wavelength of 400 nm is 3% or less.
(i-3) In a spectral transmittance curve at an incident angle of 0 degrees, a transmittance T_{400(0deg)} at a wavelength of 400 nm and a transmittance T_{430(0deg)} at a wavelength of 430 nm satisfy the following relation:

$${T}_{430 ( 0 deg )} - {T}_{400 ( 0 deg )} \geq 78 \% .$$

(i-4) In a spectral transmittance curve at an incident angle of 0 degrees, an average transmittance T_{430-600(0deg)AVE} at a wavelength of 430 nm to 600 nm is 80% or more.
(i-5) When an antireflection layer 1 side is set as an incident direction, an absolute value of a difference between an average reflectance R1_{430-600(5deg)AVE} at a wavelength of 430 nm to 600 nm in a spectral reflectance curve at an incident angle of 5 degrees and an average reflectance R1_{430-600(50deg)AVE} at a wavelength of 430 nm to 600 nm in a spectral reflectance curve at an incident angle of 50 degrees is 4% or less.
(i-6) When an antireflection layer 2 side is set as an incident direction, an absolute value of a difference between an average reflectance R2_{430-600(5deg)AVE} at a wavelength of 430 nm to 600 nm in a spectral reflectance curve at an incident angle of 5 degrees and an average reflectance R2_{430-600(50deg)AVE} at a wavelength of 430 nm to 600 nm in a spectral reflectance curve at an incident angle of 50 degrees is 4% or less.
(i-7) In a spectral transmittance curve at an incident angle of 0 degrees, an average transmittance T_{750-1100(0deg)AVE} at a wavelength of 750 nm to 1,100 nm is 2% or less.

The filter satisfying all of the spectral characteristics (i-1) to (i-7) is excellent in light-shielding properties in the near-ultraviolet region as shown in the characteristics (i-1) and (i-2), particularly capable of shielding a wide range of light up to around 400 nm as shown in the characteristic (i-2), excellent in transmittance of visible light as shown in the characteristic (i-4), and excellent in shielding properties in a near-infrared region as shown in the characteristic (i-7). In addition, as shown in the characteristic (i-3), a change in transmittance is steep from the near-ultraviolet region to the visible light region. Further, as shown in the characteristics (i-5) and (i-6), in any direction of a main surface of the optical filter, a change in reflection characteristics is small at a high incident angle, and a ripple in the visible light region is prevented.

In order to satisfy all of the spectral characteristics (i-1) to (i-7), for example, it is preferable to use a dielectric multilayer film in which the reflection characteristics are prevented, to use a phosphate glass or a fluorophosphate glass as the near-infrared ray absorbing glass, and to use a merocyanine compound having a maximum absorption wavelength in a wavelength of 370 nm to 410 nm and a zeromethine compound having a maximum absorption wavelength in a wavelength of 350 nm to 380 nm to be described later as the UV dye.

The average transmittance T_{350-390(0deg)AVE} of the characteristic (i-1) is 1% or less, preferably 0.8% or less, and more preferably 0.5% or less.

The transmittance T_{400(0deg)} of the characteristic (i-2) is 3% or less, preferably 2.5% or less, and more preferably 2% or less.

T_{430(0deg)}−T_{400(0deg)} of the characteristic (i-3) is 78% or more, preferably 79% or more, and more preferably 79.5% or more.

The average transmittance T_{430-600(0deg)AVE} of the characteristic (i-4) is 80% or more, preferably 81% or more, and more preferably 82% or more.

The absolute value of the difference between the average reflectance R1_{430-600(5deg)AVE} and the average reflectance R1_{430-600(50deg)AVE} in the characteristic (i-5) is 4% or less, preferably 3.5% or less, and more preferably 3% or less.

The absolute value of the difference between the average reflectance R2_{430-600(5deg)AVE} and the average reflectance R2_{430-600(50deg)AVE} in the characteristic (i-6) is 4% or less, preferably 3.5% or less, and more preferably 3% or less.

The average transmittance T_{750-1100(0deg)AVE} in the characteristic (i-7) is 2% or less, preferably 1.5% or less, and more preferably 1% or less.

The optical filter according to the present embodiment preferably further satisfies the following spectral characteristic (i-8).
(i-8) In a spectral transmittance curve at an incident angle of 50 degrees, a transmittance T_{400(50deg)} at a wavelength of 400 nm is 3% or less.

Accordingly, an optical filter having excellent light-shielding properties in the vicinity of 400 nm even at a high incident angle is obtained.

The transmittance T_{400(50deg)} is more preferably 2.5% or less, and further preferably 2% or less.

The optical filter according to the present embodiment preferably further satisfies the following spectral characteristic (i-9).
(i-9) In a spectral transmittance curve at an incident angle of 50 degrees, an average transmittance T_{350-390(50deg)AVE} at a wavelength of 350 nm to 390 nm is 1.5% or less.

Accordingly, an optical filter having excellent light-shielding properties in the near-ultraviolet light region of the wavelength of 350 nm to 390 nm is obtained.

The average transmittance T_{350-390(50deg)AVE} is more preferably 1.3% or less, and further preferably 1% or less.

The optical filter according to the present embodiment preferably further satisfies the following spectral characteristics (i-10) and (i-11).
(i-10) A minimum wavelength T_{(0deg)UV50} at which a transmittance is 50% in a wavelength range of 350 nm to 430 nm in a spectral transmittance curve at an incident angle of 0 degrees and a maximum wavelength R1_{(5deg)UV50} at which a reflectance is 50% in a wavelength range of 350 nm to 430 nm in a spectral reflectance curve at an incident angle of 5 degrees when an antireflection layer 1 side is set as an incident direction satisfy the following relation:

$${T}_{( 0 deg ) UV 50} - R {1}_{( 5 deg ) UV 50} > 10 nm .$$

(i-11) The T_{(0deg)UV50} and a maximum wavelength R2_{(5deg)UV50} at which a reflectance is 50% in a wavelength range of 350 nm to 430 nm in a spectral reflectance curve at an incident angle of 5 degrees when an antireflection layer 2 side is set as an incident direction satisfy the following relation:

$${T}_{( 0 deg ) UV 50} - R {2}_{( 5 deg ) UV 50} > 10 nm .$$

Accordingly, an optical filter in which a difference between cut edges of the transmittance and the reflectance is large, that is, the reflection characteristics are small and the light-shielding properties are ensured due to the absorption characteristics is obtained. In the characteristic (i-10), it is more preferable that T_{(0deg)UV50}−R1_{(5deg)UV50}>11 nm, and further preferable that T_{(0deg)UV50}−R1_{(5deg)UV50}>12 nm.

In the characteristic (i-11), it is more preferable that T_{(0deg)UV50}−R2_{(5deg)UV50}>11 nm, and further preferable that T_{(0deg)UV50}−R2_{(5deg)UV50}>12 nm.

The optical filter according to the present embodiment preferably further satisfies the following spectral characteristics (i-12) to (i-14).
(i-12) The T_{(0deg)UV50} is in a wavelength range of 400 nm to 430 nm.
(i-13) In a spectral transmittance curve at an incident angle of 50 degrees, a minimum wavelength T_{(50deg)UV50} at which a transmittance is 50% in a wavelength range of 350 nm to 430 nm is in a wavelength range of 400 nm to 430 nm.
(i-14) An absolute value of a difference between the T_{(0deg)UV50} and the T_{(50deg)UV50} is 4 nm or less.

By satisfying the characteristics (i-12) and (i-13), regions (cut edges) where a near-ultraviolet light shielding region and a visible light transmission region are switched are the same region even at a high incident angle, and by satisfying the characteristic (i-14), an optical filter having a small variation amount of the cut edge is obtained.

In the characteristic (i-12), the wavelength T_{(0deg)UV50} is more preferably in 405 nm to 430 nm, and further preferably in 410 nm to 425 nm.

In the characteristic (i-13), the wavelength T_{(50deg)UV50} is more preferably in 405 nm to 430 nm, and further preferably in 410 nm to 425 nm.

In the characteristic (i-14), the absolute value of the difference between T_{(0deg)UV50} and T_{(50deg)UV50} is more preferably 3 nm or less, and further preferably 2 nm or less.

The optical filter according to the present embodiment preferably further satisfies the following spectral characteristic (i-15).
(i-15) An average transmittance T_{430-600(0deg)AVE} at a wavelength of 430 nm to 600 nm in a spectral transmittance curve at an incident angle of 0 degrees and an average transmittance T_{430-600(50deg)AVE} at a wavelength of 430 nm to 600 nm in a spectral transmittance curve at an incident angle of 50 degrees satisfy the following relation:

$${T}_{430 - 600 ( 0 deg ) AVE} - {T}_{430 - 600 ( 50 deg ) AVE} \leq 4.5 \% .$$

Accordingly, an optical filter in which a ripple in the visible light region is small since a reflection layer is not used and the transmittance of visible light is less likely to be reduced even at a high incident angle is obtained.

T_{430-600(0deg)AVE}−T_{430-600(50deg)AVE} is more preferably 4.3% or less, and further preferably 4% or less.

The optical filter according to the present embodiment preferably further satisfies the following spectral characteristics (i-16) and (i-17).
(i-16) When an antireflection layer 1 side is set as an incident direction, an average reflectance R1_{750-1100(5deg)AVE} at a wavelength of 750 nm to 1,100 nm in a spectral reflectance curve at an incident angle of 5 degrees is 15% or less.
(i-17) When an antireflection layer 2 side is set as an incident direction, an average reflectance R2_{750-1100(5deg)AVE} at a wavelength of 750 nm to 1,100 nm in a spectral reflectance curve at an incident angle of 5 degrees is 15% or less.

Accordingly, an optical filter having small reflection characteristics in the near-infrared region is obtained.

The average reflectance R1_{750-1100(5deg)AVE} is more preferably 13% or less, and further preferably 12% or less.

The average reflectance R2_{750-1100(5deg)AVE} is more preferably 13% or less, and further preferably 12% or less.

The optical filter according to the present embodiment preferably further satisfies the following spectral characteristics (i-18) to (i-20).
(i-18) In a spectral transmittance curve at an incident angle of 0 degrees, a minimum transmittance T_{430-600(0deg)MIN} at a wavelength of 430 nm to 600 nm is 60% or more.
(i-19) In a spectral transmittance curve at an incident angle of 0 degrees, a maximum transmittance T_{430-600(0deg)MAX} at a wavelength of 430 nm to 600 nm is 90% or more.
(i-20) In a spectral transmittance curve at an incident angle of 0 degrees, a maximum transmittance T_{750-1100(0deg)MAX} at a wavelength of 750 nm to 1,100 nm is 3% or less.

An optical filter is obtained in which the transmittance of visible light is excellent by satisfying the characteristics (i-18) and (i-19), and shielding properties in the near-infrared region is excellent by satisfying the characteristic (i-20).

In the characteristic (i-18), T_{430-600(0deg)MIN} is more preferably 62% or more, and further preferably 64% or more.

In the characteristic (i-19), T_{430-600(0deg)MAX} is more preferably 91% or more, and further preferably 93% or more.

In the characteristic (i-20), T_{750-1100(0deg)MAX} is more preferably 2.5% or less, and further preferably 2% or less.

### <Substrate>

In the optical filter according to the present embodiment, the substrate includes a near-infrared ray absorbing glass and a resin film. The resin film is laminated on at least one main surface of the near-infrared ray absorbing glass, and contains a resin, a UV dye having a maximum absorption wavelength in 350 nm to 410 nm in the resin, and an IR dye having a maximum absorption wavelength in 700 nm to 850 nm in the resin. In the present embodiment, the substrate has both an absorption ability of the near-infrared ray absorbing glass and an absorption ability of the resin film containing the UV dye and the IR dye.

### <Near-Infrared Ray Absorbing Glass>

The near-infrared ray absorbing glass preferably satisfies both of the following spectral characteristics (ii-1) and (ii-2).
(ii-1) An average internal transmittance T_{450-600AVE} at a wavelength of 450 nm to 600 nm is 80% or more.
(ii-2) An average internal transmittance T_{750-1100AVE} at a wavelength of 750 nm to 1,100 nm is 5% or less.

That is, the near-infrared ray absorbing glass preferably has both a high transmittance in the visible light region and light-shielding properties in a wide near-infrared region of 750 nm to 1,100 nm.

The average internal transmittance T_{450-600AVE} is more preferably 81% or more, and further preferably 82% or more.

The average internal transmittance T_{750-1100AVE} is more preferably 4% or less, and further preferably 3% or less.

The near-infrared ray absorbing glass is not limited as long as the near-infrared ray absorbing glass is glass capable of obtaining the above spectral characteristics, and examples thereof include an absorption type glass such as a fluorophosphate glass or a phosphate glass containing copper ions. Among those, the phosphate glass is preferable from the viewpoint of easily obtaining the above spectral characteristics. The “phosphate glass” also includes a silicophosphate glass in which a part of a skeleton of the glass is formed of SiO₂.

For example, it is preferable that the phosphate glass contains the following components constituting the glass. Respective content ratios of the following glass constituent components are expressed in terms of mass percentage based on oxide:
40% to 80% of P₂O₅,
0.5% to 20% of Al₂O₃,
0.5% to 20% of ΣR₂O (where R₂O is one or more components selected from Li₂O, Na₂O, K₂O, Rb₂O, and Cs₂O, and YR₂O is a total content of R₂O), 0% to 40% of ΣR′O (where R′O is one or more components selected from CaO, MgO, BaO, SrO, and ZnO, and ΣR′O is a total content of R′O), and 0.5% to 40% of CuO.

P₂O₅ is a main component forming the glass, and is a component for enhancing a near-infrared ray cutting property. When a content of P₂O₅ is 40% or more, an effect thereof can be sufficiently obtained, and when the content of P₂O₅ is 80% or less, problems such as glass instability and reduction in weather resistance are less likely to occur. Therefore, the content of P₂O₅ is preferably 40% to 80%, more preferably 45% to 78%, further preferably 50% to 77%, still more preferably 55% to 76%, and most preferably 60% to 75%.

Al₂O₃ is a main component forming glass, and is a component for enhancing strength of the glass, enhancing the weather resistance of the glass, and the like. When a content of Al₂O₃ is 0.5% or more, an effect thereof can be sufficiently obtained, and when the content of Al₂O₃ is 20% or less, problems such as glass instability and reduction in near-infrared ray cutting property are less likely to occur. Therefore, the content of Al₂O₃ is preferably 0.5% to 20%, more preferably 1.0% to 20%, further preferably 2.0% to 18%, still more preferably 3.0% to 17%, particularly preferably 4.0% to 16%, and most preferably 5.0% to 15.5%.

R₂O (where R₂O is one or more components selected from Li₂O, Na₂O, K₂O, Rb₂O, and Cs₂O) is a component for lowering a melting temperature of the glass, lowering a liquid phase temperature of the glass, stabilizing the glass, and the like. When a total content of R₂O (ΣR₂O) is 0.5% or more, an effect thereof is sufficiently obtained, and when the total content of R₂O is 20% or less, glass instability is less likely to occur, which is preferable. Therefore, the total content of R₂O is preferably 0.5% to 20%, more preferably 1.0% to 19%, further preferably 1.5% to 18%, still more preferably 2.0% to 17%, particularly preferably 2.5% to 16%, and most preferably 3% to 15.5%.

Li₂O is a component for lowering the melting temperature of the glass, lowering the liquid phase temperature of the glass, stabilizing the glass, and the like. A content of Li₂O is preferably 0% to 15%. When the content of Li₂O is 15% or less, problems such as glass instability and reduction in near-infrared ray cutting property are less likely to occur, which is preferable. The content of Li₂O is more preferably 0% to 8%, further preferably 0% to 7%, still more preferably 0% to 6%, and most preferably 0% to 5%.

Na₂O is a component for lowering the melting temperature of the glass, lowering the liquid phase temperature of the glass, stabilizing the glass, and the like. A content of Na₂O is preferably 0% to 15%. When the content of Na₂O is 15% or less, glass instability is less likely to occur, which is preferable. The content of Na₂O is more preferably 0.5% to 14%, further preferably 1% to 13%, still more preferably 2% to 13%, and most preferably 3% to 13%.

K₂O is a component having effects such as lowering the melting temperature of the glass and lowering the liquid phase temperature of the glass. A content of K₂O is preferably 0% to 20%. When the content of K₂O is 20% or less, glass instability is less likely to occur, which is preferable. The content of K₂O is more preferably 0.5% to 19%, further preferably 1% to 18%, still more preferably 2% to 17%, and most preferably 3% to 16%.

Rb₂O is a component having effects such as lowering the melting temperature of the glass and lowering the liquid phase temperature of the glass. A content of Rb₂O is preferably 0% to 15%. When the content of Rb₂O is 15% or less, glass instability is less likely to occur, which is preferable. The content of Rb₂O is more preferably 0.5% to 14%, further preferably 1% to 13%, still more preferably 2% to 13%, and most preferably 3% to 13%.

Cs₂O is a component having effects such as lowering the melting temperature of the glass and lowering the liquid phase temperature of the glass. A content of Cs₂O is preferably 0% to 15%. When the content of Cs₂O is 15% or less, glass instability is less likely to occur, which is preferable. The content of Cs₂O is more preferably 0.5% to 14%, further preferably 1% to 13%, still more preferably 2% to 13%, and most preferably 3% to 13%.

When two or more of the above alkali metal components represented by R₂O are added at the same time, a mixed alkali effect is generated in the glass, and a mobility of R⁺ ions is reduced. Accordingly, when the glass comes into contact with water, a hydration reaction caused by ion exchange between H⁺ ions in water molecules and the R⁺ ions in the glass is inhibited, and the weather resistance of the glass is improved. Therefore, the phosphate glass of the present embodiment preferably contains two or more components selected from Li₂O, Na₂O, K₂O, Rb₂O, and Cs₂O. In this case, the total content (ΣR₂O) of R₂O (where R₂O is Li₂O, Na₂O, K₂O, Rb₂O, and Cs₂O) is preferably more than 7% and 18% or less. When the total content of R₂O is more than 7%, the effect thereof is sufficiently obtained, and when the total content of R₂O is 18% or less, problems such as glass instability, reduction in near-infrared ray cutting property, and reduction in strength of the glass are less likely to occur, which is preferable. Therefore, ΣR₂O is preferably more than 7% and 18% or less, more preferably 7.5% to 17%, further preferably 8% to 16%, still more preferably 8.5% to 15%, and most preferably 9% to 14%.

R′O (where R′O is one or more components selected from CaO, MgO, BaO, SrO, and ZnO) is a component for lowering the melting temperature of the glass, lowering the liquid phase temperature of the glass, stabilizing the glass, enhancing the strength of the glass, and the like. A total content of R′O (ΣR′O) is preferably 0% to 40%. When the total content of R′O is 40% or less, problems such as glass instability, reduction in near-infrared ray cutting property, and reduction in strength of the glass are less likely to occur, which is preferable. The total content of R′O is more preferably 0% to 35%, and further preferably 0% to 30%. The total content of R′O is still more preferably 0% to 25%, particularly preferably 0% to 20%, and most preferably 0% to 15%.

CaO is a component for lowering the melting temperature of the glass, lowering the liquid phase temperature of the glass, stabilizing the glass, enhancing the strength of the glass, and the like. A content of CaO is preferably 0% to 10%. When the content of CaO is 10% or less, problems such as glass instability and reduction in near-infrared ray cutting property are less likely to occur, which is preferable. The content of CaO is more preferably 0% to 8%, further preferably 0% to 6%, still more preferably 0% to 5%, and most preferably 0% to 4%.

MgO is a component for lowering the melting temperature of the glass, lowering the liquid phase temperature of the glass, stabilizing the glass, enhancing the strength of the glass, and the like. A content of MgO is preferably 0% to 15%. When the content of MgO is 15% or less, problems such as glass instability and reduction in near-infrared ray cutting property are less likely to occur, which is preferable. The content of MgO is more preferably 0% to 13%, further preferably 0% to 10%, still more preferably 0% to 9%, and most preferably 0% to 8%.

BaO is a component for lowering the melting temperature of the glass, lowering the liquid phase temperature of the glass, stabilizing the glass, and the like. A content of BaO is preferably 0% to 40%. When the content of BaO is 40% or less, problems such as glass instability and reduction in near-infrared ray cutting property are less likely to occur, which is preferable. The content of BaO is more preferably 0% to 30%, further preferably 0% to 20%, still more preferably 0% to 10%, and most preferably 0% to 5%.

SrO is a component for lowering the melting temperature of the glass, lowering the liquid phase temperature of the glass, stabilizing the glass, and the like. A content of SrO is preferably 0% to 10%. When the content of SrO is 10% or less, problems such as glass instability and reduction in near-infrared ray cutting property are less likely to occur, which is preferable. The content of SrO is more preferably 0% to 8%, further preferably 0% to 7%, and most preferably 0% to 6%.

ZnO has effects such as lowering the melting temperature of the glass and lowering the liquid phase temperature of the glass. A content of ZnO is preferably 0% to 15%. When the content of ZnO is 15% or less, problems such as glass instability, deterioration in solubility of the glass, and reduction in near-infrared ray cutting property are less likely to occur, which is preferable. The content of ZnO is more preferably 0% to 13%, further preferably 0% to 10%, still more preferably 0% to 9%, and most preferably 0% to 8%.

CuO is a component for enhancing the near-infrared ray cutting property. A content of CuO is preferably 0.5% to 40%. When the content of CuO is 0.5% or more, an effect thereof can be sufficiently obtained, and when the content of CuO is 40% or less, problems such as generation of devitrification foreign matters in the glass and reduction in transmittance of light in a visible region are less likely to occur, which is preferable. The content of CuO is more preferably 1.0% to 35%, further preferably 1.5% to 30%, still more preferably 2.0% to 25%, and most preferably 2.5% to 20%.

F may be contained in a range of 10% or less in order to enhance the weather resistance. When a content of F is 10% or less, problems such as reduction in near-infrared ray cutting property and generation of devitrification foreign matters in the glass are less likely to occur, which is preferable. The content of F is more preferably 9% or less, further preferably 8% or less, still more preferably 7% or less, particularly preferably 6% or less, and most preferably 5% or less.

B₂O₃ may be contained in a range of 10% or less for stabilizing the glass. When a content of B₂O₃ is 10% or less, problems such as deterioration in weather resistance of the glass and reduction in near-infrared ray cutting property are less likely to occur, which is preferable. The content of B₂O₃ is more preferably 9% or less, further preferably 8% or less, still more preferably 7% or less, particularly preferably 6% or less, and most preferably 5% or less.

In the present embodiment, SiO₂, GeO₂, ZrO₂, SnO₂, TiO₂, CeO₂, MoO₃, WO₃, Y₂O₃, La₂O₃, Gd₂O₃, Yb₂O₃, and Nb₂O₅ may be contained in a range of 5% or less in order to improve the weather resistance of the phosphate glass. When a content of these components is 5% or less, problems such as generation of devitrification foreign matters in the glass and reduction in near-infrared ray cutting property are less likely to occur, which is preferable. The content of these components is preferably 4% or less, more preferably 3% or less, further preferably 2% or less, and still more preferably 1% or less.

Any of Fe₂O₃, Cr₂O₃, Bi₂O₃, NiO, V₂O₅, MnO₂, and CoO is a component that reduces the transmittance of light in the visible region by being present in the phosphate glass. Therefore, it is preferable that these components are not substantially contained in the glass. In the present invention, the expression “a specific component is not substantially contained” means that the component is not intentionally added, and does not exclude inclusion of the component to the extent that the component is unavoidably mixed in from raw materials, or the like, and does not affect desired properties.

The thickness of the near-infrared ray absorbing glass is preferably 0.5 mm or less and more preferably 0.3 mm or less from the viewpoint of reduction in height of camera modules, and is preferably 0.15 mm or more from the viewpoint of element strength.

The phosphate glass can be prepared as follows, for example.

First, raw materials are weighed and mixed so as to fall within the above composition range (mixing step). The raw material mixture is accommodated in a platinum crucible, and heated and melted at a temperature of 700° C. to 1,400° C. in an electric furnace (melting step). After being sufficiently stirred and refined, the raw material mixture is cast into a mold, cut and polished to form a flat plate having a predetermined thickness (molding step).

In the melting step of the above manufacturing method, the highest temperature of the glass during glass melting is preferably 1,400° C. or lower. When the highest temperature of the glass during glass melting is higher than the above temperature, transmittance characteristics may deteriorate. The above temperature is more preferably 1,350° C. or lower, further preferably 1,300° C. or lower, and still more preferably 1,250° C. or lower.

When the temperature in the above melting step is too low, problems such as occurrence of devitrification during melting and requirement of a long time for burn through may occur, and thus the temperature is preferably 700° C. or higher, and more preferably 800° C. or higher.

### <UV Dye>

The UV dye is not limited as long as the UV dye is a compound having a maximum absorption wavelength in 350 nm to 410 nm in the resin, but the UV dye preferably contain at least one of the merocyanine compound having a maximum absorption wavelength in 370 nm to 410 nm in the resin and the zeromethine compound having a maximum absorption wavelength in 350 nm to 380 nm in the resin, and more preferably contain both the merocyanine compound and the zeromethine compound from the viewpoint of efficiently shielding light in a wide near-ultraviolet light region.

The resin is a resin used for the resin film in the optical filter according to the present embodiment.

### (Merocyanine Compound)

The merocyanine compound is preferably a compound represented by the following formula (M).

The compound represented by the following formula (M) is preferable because the dye compound itself has excellent light resistance and is less likely to be photodegraded. The compound is preferable also from the viewpoint of not affecting light resistance of the IR dye even when being used in combination with the IR dye.

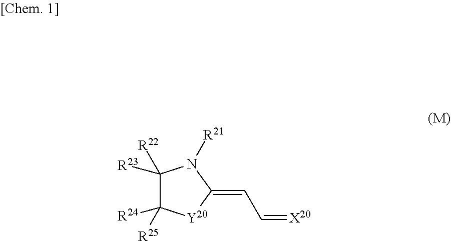

### [Definitions of Symbols in the Formula (M) are as Follows:

R²¹ represents a monovalent hydrocarbon group having 1 to 16 carbon atoms which may have a substituent,
R²² to R²⁵ each independently represent a hydrogen atom, a halogen atom, an alkyl group having 1 to 10 carbon atoms, or an alkoxy group having 1 to 10 carbon atoms,
Y²⁰ represents a methylene group substituted with R²⁶ and R²⁷ or an oxygen atom, and
X²⁰ represents any of divalent groups represented by the following formulae (X1) to (X5):

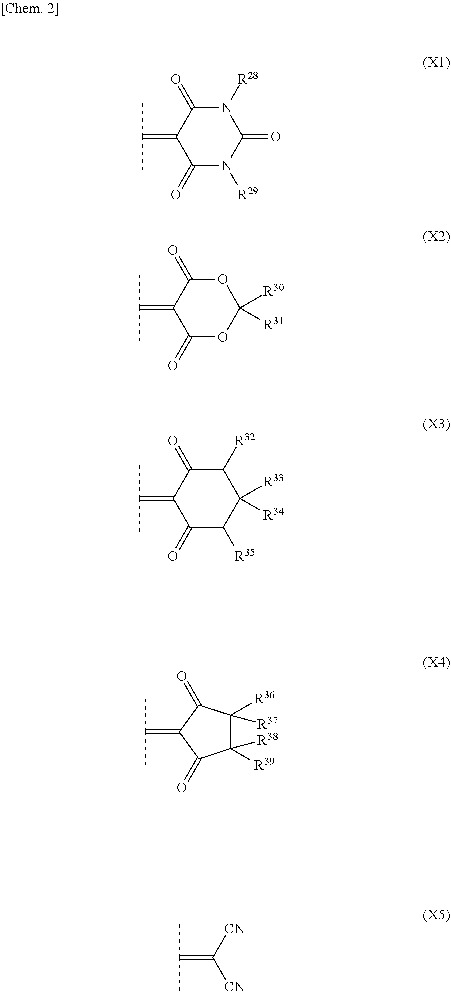

R²⁸ and R²⁹ each independently represent a monovalent hydrocarbon group having 1 to 12 carbon atoms which may have a substituent, and R³⁰ to R³⁹ each independently represent a hydrogen atom or a monovalent hydrocarbon group having 1 to 12 carbon atoms which may have a substituent.]

In the formula (M), R²¹ represents a monovalent hydrocarbon group having 1 to 12 carbon atoms which may have a substituent. The substituent is preferably an alkoxy group, an acyl group, an acyloxy group, a cyano group, a dialkylamino group, or a chlorine atom. The above alkoxy group, acyl group, acyloxy group, and dialkylamino group preferably have 1 to 6 carbon atoms.

Preferred R²¹ is an alkyl group having 1 to 6 carbon atoms in which a part of hydrogen atoms may be substituted with a cycloalkyl group or a phenyl group. Particularly preferred R²¹ is an alkyl group having 1 to 6 carbon atoms, and specific examples thereof include a methyl group, an ethyl group, an n-propyl group, an isopropyl group, an n-butyl group, an isobutyl group, and a t-butyl group.

R²² to R²⁵ each independently represent a hydrogen atom, a halogen atom, an alkyl group having 1 to 10 carbon atoms, or an alkoxy group having 1 to 10 carbon atoms. The alkyl group and the alkoxy group preferably have 1 to 6 carbon atoms, and more preferably 1 to 4 carbon atoms.

At least one of R²² and R²³ is preferably an alkyl group, and both are more preferably alkyl groups. In the case where R²² and R²³ are not alkyl groups, the two are more preferably hydrogen atoms. Both R²² and R²³ are particularly preferably alkyl groups having 1 to 6 carbon atoms.

At least one of R²⁴ and R²⁵ is preferably a hydrogen atom, and both are more preferably hydrogen atoms. In the case where R²⁴ and R²⁵ are not hydrogen atoms, the two are preferably alkyl groups having 1 to 6 carbon atoms.

Y²⁰ represents a methylene group substituted with R²⁶ and R²⁷ or an oxygen atom. R²⁶ and R²⁷ each independently represent a hydrogen atom, a halogen atom, an alkyl group having 1 to 10 carbon atoms, or an alkoxy group having 1 to 10 carbon atoms.

X²⁰ represents any of divalent groups represented by the above formulae (X1) to (X5).

R²⁸ and R²⁹ each independently represent a monovalent hydrocarbon group having 1 to 12 carbon atoms which may have a substituent, and R³⁰ to R³⁹ each independently represent a hydrogen atom or a monovalent hydrocarbon group having 1 to 12 carbon atoms which may have a substituent.

Examples of substituents of R²⁸ to R³⁹ include the same substituent as the substituent of R²¹, and the same applies to preferred aspects thereof. In the case where R²⁸ to R³⁹ are hydrocarbon groups which do not have a substituent, examples thereof include the same aspects as those of R²¹ which does not have a substituent.

Preferred R²⁸ and R²⁹ are both alkyl groups having 1 to 6 carbon atoms in which a part of hydrogen atoms may be substituted with a cycloalkyl group or a phenyl group. Particularly preferred R²⁸ and R²⁹ both represent alkyl groups having 1 to 6 carbon atoms, and specific examples thereof include a methyl group, an ethyl group, an n-propyl group, an isopropyl group, an n-butyl group, an isobutyl group, and a t-butyl group.

In the formula (X2), both R³⁰ and R³¹ are more preferably alkyl groups having 1 to 6 carbon atoms, and particularly preferably the same alkyl group.

In the formula (X3), both R³² and R³¹ are preferably hydrogen atoms or alkyl groups having 1 to 6 carbon atoms which do not have a substituent. Both R³³ and R³⁴, which are two groups bonded to the same carbon atom, are preferably hydrogen atoms or alkyl groups having 1 to 6 carbon atoms.

All of R³⁶ and R³⁷ as well as R³⁸ and R³⁹ in the formula (X4), which are two groups bonded to the same carbon atom, are preferably hydrogen atoms or alkyl groups having 1 to 6 carbon atoms.

The compound represented by the formula (M) is preferably a compound in which Y²⁰ is an oxygen atom and X²⁰ is a group (X1), a group (X2), or a group (X5), or a compound in which Y²⁰ is an unsubstituted methylene group and X²⁰ is a group (X1), a group (X2), or a group (X5).

Specific examples of the compound (M) include compounds shown in the following table.

TABLE 1

| Dye | | | | | | | | |
|---|---|---|---|---|---|---|---|---|
| abbreviation | R²¹ | R²², R²³ | R²⁴, R²⁵ | X²⁰ | Y²⁰ | R²⁶, R²⁷ | R²⁸, R²⁹ | R³⁰, R³¹ |
| (M-1) | CH₃ | H | H | X1 | O | — | CH₃ | — |
| (M-2) | CH₃ | CH₃ | H | X1 | O | — | CH₃ | — |
| (M-3) | C₂H₅ | H | H | X1 | O | — | CH₃ | — |
| (M-4) | C₂H₅ | CH₃ | H | X1 | O | — | CH₃ | — |
| (M-5) | C₃H₇ | H | H | X1 | O | — | CH₃ | — |
| (M-6) | C₃H₇ | CH₃ | H | X1 | O | — | CH₃ | — |
| (M-7) | CH(CH₃)₂ | H | H | X1 | O | — | CH₃ | — |
| (M-8) | CH(CH₃)₂ | CH₃ | H | X1 | O | — | CH₃ | — |
| (M-9) | CH₃ | H | H | X1 | —C(R²⁶)(R²⁷)— | H | CH₂CH(CH₃)₂ | — |
| (M-10) | C₂H₅ | H | H | X1 | —C(R²⁶)(R²⁷)— | H | CH₂CH(CH₃)₂ | — |
| (M-11) | C₃H₇ | H | H | X1 | —C(R²⁶)(R²⁷)— | H | CH₂CH(CH₃)₂ | — |
| (M-12) | CH(CH₃)₂ | H | H | X1 | —C(R²⁶)(R²⁷)— | H | CH₂CH(CH₃)₂ | — |
| (M-13) | CH₃ | CH₃ | H | X2 | O | — | — | CH₃ |
| (M-14) | C₂H₅ | CH₃ | H | X2 | O | — | — | CH₃ |
| (M-15) | C₃H₇ | CH₃ | H | X2 | O | — | — | CH₃ |
| (M-16) | CH(CH₃)₂ | CH₃ | H | X2 | O | — | — | CH₃ |
| (M-17) | CH₃ | H | H | X5 | —C(R²⁶XR²⁷)— | H | — | — |
| (M-18) | C₂H₅ | H | H | X5 | —C(R²⁶XR²⁷)— | H | — | — |
| (M-19) | C₃H₇ | H | H | X5 | —C(R²⁶XR²⁷)— | H | — | — |
| (M-20) | CH(CH₃)₂ | H | H | X5 | —C(R²⁶XR²⁷)— | H | — | — |

The compound (M) is preferably a compound (M-2), a compound (M-8), a compound (M-9), a compound (M-13), or a compound (M-20) from the viewpoint that solubility in a resin and a maximum absorption wavelength are appropriate.

The compound (M) can be manufactured, for example, by a known method disclosed in JP6504176B.

### (Zeromethine Compound)

The zeromethine compound is preferably a compound represented by the following formula (I).

The compound represented by the following formula (I) is preferable because the dye compound itself has excellent light resistance and is less likely to be photodegraded. The compound is preferable also from the viewpoint of not affecting light resistance of the IR dye even when being used in combination with the JR dye.

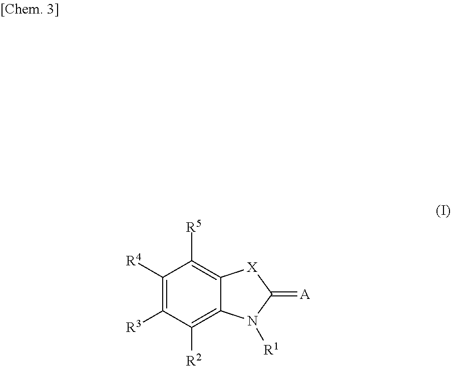

### [Definitions of Symbols in the Formula (I) are as Follows:

X represents an oxygen atom, a sulfur atom, N—R¹⁴, or C—R¹⁵R¹⁶ (R¹⁴ to R¹⁶ each independently represent a hydrogen atom or an alkyl group having 1 to 10 carbon atoms which may have a substituent),
R¹ represents an alkyl group having 1 to 6 carbon atoms which may have a substituent,
R² to R⁵ each independently represent a hydrogen atom, a halogen atom, an alkyl group having 1 to 10 carbon atoms which may have a substituent, an alkoxy group having 1 to 10 carbon atoms which may have a substituent, a nitro group, an amino group, or an amide group, and
A represents any of divalent groups represented by the following formulae (A1) to (A4):

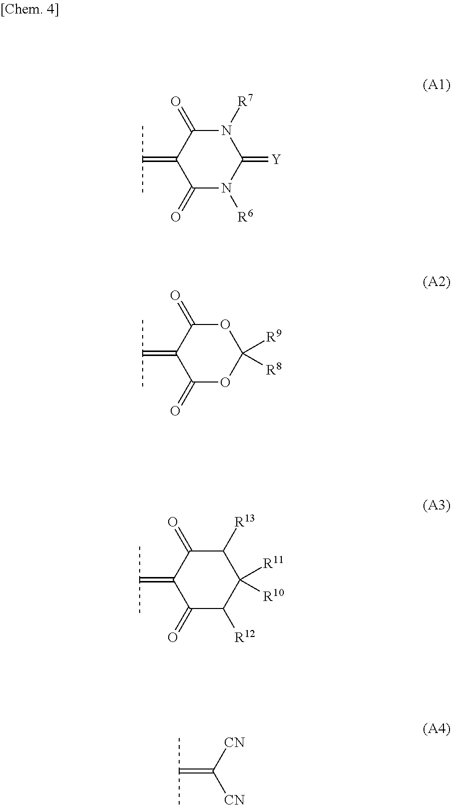

in the formulae (A1) to (A4), Y represents an oxygen atom or a sulfur atom, and R⁶ to R¹³ each independently represent a hydrogen atom or an alkyl group having 1 to 10 carbon atoms which may have a substituent.]

In the compound (I), X represents an oxygen atom, a sulfur atom, N—R¹⁴, or C—R¹⁵R¹⁶, R¹⁴ to R¹⁶ each independently represent a hydrogen atom or an alkyl group having 1 to 10 carbon atoms which may have a substituent. Examples of the substituent which may be included include an alkoxy group, an acyl group, an acyloxy group, a cyano group, a dialkylamino group, and a chlorine atom.
R¹⁴ to R¹⁶ each independently preferably represent a hydrogen atom or an alkyl group having 1 to 8 carbon atoms which may have a substituent.
X is preferably an oxygen atom, a sulfur atom, or C—R¹⁵R¹⁶, and more preferably an oxygen atom or a sulfur atom. That is, the compound (I) is more preferably a compound represented by the following formula (I)′.

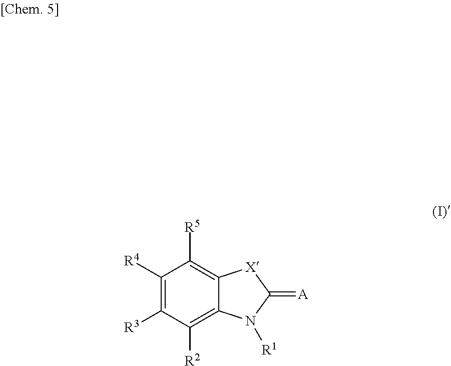

(In the formula (I)′, X′ represents an oxygen atom or a sulfur atom, R¹ represents an alkyl group having 1 to 6 carbon atoms which may have a substituent, R² to R⁵ each independently represent a hydrogen atom, a halogen atom, an alkyl group or alkoxy group having 1 to 10 carbon atoms which may have a substituent, a nitro group, an amino group, or an amide group, and A represents any of divalent groups represented by the above formulae (A1) to (A4)).

In the compound (I) or the compound (I)′, R¹ is an alkyl group having 1 to 6 carbon atoms which may have a substituent. Examples of the substituent which may be included include an alkoxy group, an acyl group, an acyloxy group, a cyano group, a dialkylamino group, and a chlorine atom.

R¹ is preferably an alkyl group having 1 to 6 carbon atoms, more preferably an alkyl group having 1 to 3 carbon atoms, and further preferably a methyl group.

In the compound (I) or the compound (I)′, R² to R⁵ each independently represent a hydrogen atom, a halogen atom, an alkyl group or alkoxy group having 1 to 10 carbon atoms which may have a substituent, a nitro group, an amino group, or an amide group. Examples of the substituent which may be included include an alkoxy group, an acyl group, an acyloxy group, a cyano group, a dialkylamino group, and a chlorine atom.

R² is preferably a hydrogen atom, an alkyl group having 1 to 6 carbon atoms, or a halogen atom, and more preferably a hydrogen atom. R³ is preferably a hydrogen atom, an alkyl group having 1 to 6 carbon atoms, or an alkoxy group having 1 to 6 carbon atoms, and more preferably a hydrogen atom or an alkyl group having 1 to 6 carbon atoms. R⁴ is preferably a hydrogen atom, an alkyl group having 1 to 6 carbon atoms, or a halogen atom, and more preferably a hydrogen atom. R⁵ is preferably a hydrogen atom, an alkyl group having 1 to 6 carbon atoms, or a halogen atom, and more preferably a hydrogen atom.

In the compound (I) or the compound (I)′, A represents any of the divalent groups represented by the above formulae (A1) to (A4), and is preferably a divalent group represented by the formula (A1) or (A3).

In the divalent group represented by the formula (A1), Y is an oxygen atom or a sulfur atom. In the case where X in the formula (I) or X′ in the formula (I)′ is a sulfur atom, Y is preferably an oxygen atom. In the case where Y is a sulfur atom, X is preferably an oxygen atom, N—R¹⁴, or C—R¹⁵R¹⁶ and more preferably an oxygen atom, and X′ is preferably an oxygen atom.

Further, at least one of X or X′ and Y is preferably an oxygen atom.

In the divalent groups represented by the formulae (A1) to (A4), R⁶ to R¹³ each independently represent a hydrogen atom, an alkyl group having 1 to 10 carbon atoms which may have a substituent, or a phenyl group. Examples of the substituent which may be included include an alkoxy group, an acyl group, an acyloxy group, a cyano group, a dialkylamino group, and a chlorine atom.

R⁶ and R⁷ each independently preferably represent a hydrogen atom, an alkyl group having 1 to 6 carbon atoms, or a phenyl group, and more preferably an alkyl group having 1 to 6 carbon atoms.

R⁸ and R⁹ each independently preferably represent a hydrogen atom, an alkyl group having 1 to 6 carbon atoms, or a phenyl group, and more preferably an alkyl group having 1 to 6 carbon atoms.

R¹⁰ and R¹¹ each independently preferably represent a hydrogen atom, an alkyl group having 1 to 6 carbon atoms, or a phenyl group, and more preferably an alkyl group having 1 to 6 carbon atoms. R¹² and R¹³ each independently preferably represent a hydrogen atom or an alkyl group having 1 to 6 carbon atoms, and more preferably a hydrogen atom.

More specifically, the compound (I) or the compound (I)′ includes compounds in which atoms or groups bonded to each skeleton are shown in Table 2 below. In the table, i-Bu means an isobutyl group, t-Bu means a tertiary butyl group, and Ph means a phenyl group.

TABLE 2

| | | | | | | | | R⁶ | R⁷ | | |
|---|---|---|---|---|---|---|---|---|---|---|---|
| Dye | | | | | | | | R⁸ | R⁹ | Y | |
| abbreviation | R¹ | R² | R³ | R⁴ | R⁵ | X | A | R¹⁰ | R¹¹ | R¹² | R¹³ |
| 1-1 | CH₃ | H | H | H | H | S | A1 | CH₃ | CH₃ | O | — |
| 1-2 | CH₃ | H | H | H | H | S | A1 | i-Bu | i-Bu | O | — |
| 1-3 | CH₃ | H | t-Bu | H | H | O | A1 | C₂H₅ | C₂H₅ | S | — |
| 1-4 | CH₃ | H | OCH₃ | H | H | O | A1 | CH₃ | CH₃ | S | — |
| 1-5 | CH₃ | H | H | H | H | O | A1 | CH₃ | CH₃ | O | — |
| 1-6 | CH₃ | H | H | H | H | S | A1 | Ph | Ph | O | — |
| 1-7 | CH₃ | H | H | H | H | S | A2 | CH₃ | CH₃ | — | — |
| 1-8 | CH₃ | H | H | H | H | S | A3 | CH₃ | CH₃ | H | — |
| 1-9 | CH₃ | H | H | H | H | S | A3 | Ph | H | H | H |
| 1-10 | CH₃ | H | H | H | H | S | A4 | — | — | — | — |

Among the above, compounds having dye abbreviations of I-1, I-2, I-3, and I-8 are particularly preferred.

A method for manufacturing the compound (I) or the compound (I)′ is not particularly limited, and for example, an intermediate 1 represented by the following formula is obtained by causing 2-(methylthio)benzothiazole and methyl p-toluene sulfonate to react. In the formula, Ts represents a tosyl group.

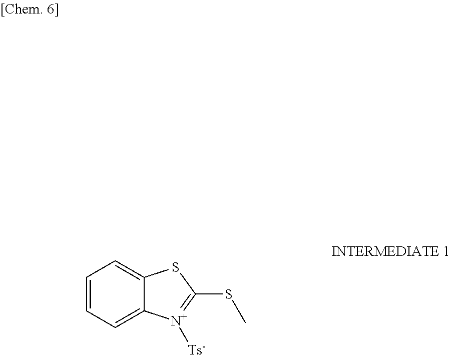

The above intermediate 1 is caused to react with a compound corresponding to the divalent groups represented by the formulae (A1) to (A4) in the presence of a solvent to obtain the compound (I) or compound (I)′.

By changing the above 2-(methylthio)benzothiazole to a 2-(methylthio)benzothiazole derivative in which hydrogen atoms corresponding to R¹ to R⁵ are changed to substituents, or to a 2-(methylthio)benzoxazole or 2-(methylthio)indole derivative, the compound (I) or compound (I)′ having a desired structure can be obtained.

A content of the UV dye in the resin film is preferably in a range such that the product of the content of the UV dye in terms of mass % and a thickness of the resin film is preferably 20.0 (mass %·μm) or less, more preferably 19.0 (mass %·μm) or less, and particularly preferably 18.0 (mass %·μm) or less. When the content of the UV dye is within the above range, a reduction of resin characteristics can be prevented, and good adhesion to the dielectric multilayer film or the near-infrared ray absorbing glass can be maintained. In addition, a reduction in heat resistance caused by a reduction in a glass transition temperature of the resin can be prevented.

Further, from the viewpoint of satisfying desired spectral characteristics, the above product is preferably 3.0 (mass %·μm) or more, and more preferably 5.0 (mass %·μm) or more.

When a plurality of compounds are used as the UV dye, a product of a total content of the plurality of UV dyes and the thickness of the resin film preferably satisfies the above range.

From the viewpoint that the product of the content of the UV dye and the thickness of the resin film satisfies the above range, it is preferable that the content of the UV dye in the resin film is preferably 3.0 parts by mass or more and more preferably 5.0 parts by mass or more, and is preferably 15.0 parts by mass or less and more preferably 14.0 parts by mass or less, with respect to 100 parts by mass of the resin.

When a plurality of compounds are used as the UV dye, a total content of the plurality of UV dyes preferably satisfies the above range.

### <IR Dye>

The IR dye is not limited as long as the IR dye is a compound having a maximum absorption wavelength in 700 nm to 850 nm in the resin, and for example, the IR dye is preferably at least one selected from the group consisting of a squarylium dye, a cyanine dye, a phthalocyanine dye, a naphthalocyanine dye, a dithiol metal complex dye, an azo dye, a polymethine dye, a phthalide dye, a naphthoquinone dye, an anthraquinone dye, an indophenol dye, a pyrylium dye, a thiopyrylium dye, a croconium dye, a tetradehydrocholine dye, a triphenylmethane dye, an aminium dye, and a diimmonium dye, and more preferably contains at least one dye selected from the group consisting of a squarylium dye, a phthalocyanine dye, and a cyanine dye.

Among these IR dyes, a squarylium dye and a cyanine dye are preferable from a spectroscopic viewpoint, and a phthalocyanine dye is preferable from the viewpoint of durability.

A content of the IR dye in the resin film is preferably 3.0 parts by mass or more and more preferably 5.0 parts by mass or more, and is preferably 25.0 parts by mass or less and more preferably 20.0 parts by mass or less, with respect to 100 parts by mass of a transparent resin.

### <Resin>

The resin contained in the resin film is not particularly limited as long as the resin is a transparent resin that transmits visible light having a wavelength of 400 nm to 700 nm.

Examples of the transparent resin include a polyester resin, an acrylic resin, an epoxy resin, an enethiol resin, a polycarbonate resin, a polyether resin, a polyarylate resin, a polysulfone resin, a polyethersulfone resin, a polyparaphenylene resin, a polyarylene ether phosphine oxide resin, a polyamide resin, a polyimide resin, a polyamide-imide resin, a polyolefin resin, a cyclic olefin resin, a polyurethane resin, a polystyrene resin, and the like. These transparent resins may be used alone, or may be used by mixing two or more kinds thereof. Among those, a polyimide resin is preferable from the viewpoint that a visible light transmittance is excellent, a glass transition temperature of the resin is high, and thermal degradation of the dye is less likely to occur.

The optical filter may have one layer of the resin film, or may have two or more layers of the resin film. When the optical filter has two or more layers of the resin film, respective resin films may have the same configuration or different configurations.

The thickness of the resin film is preferably 5 μm or less and more preferably 3 μm or less from the viewpoint of obtaining a uniform film having a small film thickness distribution. The thickness of the resin film is preferably 0.5 μm or more and more preferably 1 μm or more from the viewpoint of obtaining the desired spectral characteristics. When the optical filter according to the present embodiment includes two or more resin films, the thickness of each resin film preferably satisfies the above range.

### <Dielectric Multilayer Film>

In the filter, dielectric multilayer films are laminated as outermost layers on both main surfaces of the substrate. Each of the dielectric multilayer films is designed as an antireflection layer having small reflection characteristics in an ultraviolet light region, the visible light region, and the near-infrared light region.

For example, the antireflection layer is formed of a dielectric multilayer film in which two or more of a dielectric film having a low refractive index (low refractive index film), a dielectric film having a medium refractive index (medium refractive index film), and a dielectric film having a high refractive index (high refractive index film) are laminated.

In the optical filter, a ripple of visible light occurs due to interference caused by reflected light at interfaces of respective layers when the dielectric multilayer film is laminated as a reflection layer. Accordingly, by laminating the dielectric multilayer film as an antireflection layer as described above, an optical filter in which the ripple of visible light is prevented can be obtained.

In the present description, the antireflection layer means a layer having no wavelength band having a width of 100 nm or more in which the reflectance is 90% or more in a spectral reflectance curve at a wavelength of 750 nm to 1,200 nm and an incident angle of 5 degrees, and the reflection layer means a layer having a wavelength band having a width of 100 nm or more in which the reflectance is 90% or more in the spectral reflectance curve at a wavelength of 750 nm to 1,200 nm and an incident angle of 5 degrees, or a layer designed such that an absolute value of a difference between an average reflectance at a wavelength of 430 nm to 600 nm in a spectral reflectance curve at an incident angle of 5 degrees and an average reflectance at the wavelength of 430 nm to 600 nm in a spectral reflectance curve at an incident angle of 50 degrees on a surface on which the antireflection layer of the optical filter is laminated is 4% or less.

A refractive index of the high refractive index film is preferably 1.6 or more, and more preferably 2.2 to 2.5. Examples of a material of the high refractive index film include Ta₂O₅, TiO₂, TiO, and Nb₂O₅. Other commercially available products thereof include OS50 (Ti₃O₅), OS10 (Ti₄O₇), OA500 (mixture of Ta₂O₅ and ZrO₂), and OA600 (mixture of Ta₂O₅ and TiO₂) manufactured by Canon Optron, Inc. Among those, TiO₂ is preferable from the viewpoint of reproducibility in film formability and refractive index, stability, and the like.

A refractive index of the medium refractive index film is preferably 1.6 or more and less than 2.2. Examples of a material of the medium refractive index film include ZrO₂, Nb₂O₅, Al₂O₃, HfO₂, OM-4, OM-6 (mixtures of Al₂O₃ and ZrO₂), and OA-100 sold by Canon Optron, Inc. and H4 and M2 (alumina lanthania) sold by Merck KGaA. Among those, Al₂O₃-based compounds and mixtures of Al₂O₃ and ZrO₂ are preferable from the viewpoint of reproducibility in film formability and refractive index, stability, and the like.

A refractive index of the low refractive index film is preferably less than 1.6, and more preferably 1.45 or more and less than 1.55. Examples of a material of the low refractive index film include SiO₂, SiOₓN_{y}, and MgF₂. Other commercially available products thereof include S4F and S5F (mixtures of SiO₂ and Al₂O₃) manufactured by Canon Optron, Inc. Among those, SiO₂ is preferable from the viewpoint of reproducibility in film formability, stability, economic efficiency, and the like.

In order to obtain a dielectric multilayer film in which reflection characteristics are prevented, several types of dielectric films having different spectral characteristics may be combined when transmitting and selecting a desired wavelength band.

In the antireflection layer, the total number of laminated layers of the dielectric multilayer film is preferably 20 or less, more preferably 18 or less, and further preferably 15 or less, and is preferably 5 or more. In order to prevent reflection in a visible wavelength band even when the incident angle is changed, a film having a low reflectance in the entire wavelength band is preferable rather than a film that reflects light of a specific wavelength.

A film thickness of the antireflection layer as a whole is preferably 1 μm or less, and more preferably 0.9 μm or less, and is preferably 0.2 μm or more.

It is preferable that the antireflection layer 1 and the antireflection layer 2 satisfy the above number of laminated layers and film thickness, respectively.

For formation of the dielectric multilayer film, for example, a vacuum film formation process such as a CVD method, a sputtering method, or a vacuum deposition method, a wet film formation process such as a spraying method or a dipping method, or the like can be used.

The antireflection layer may provide predetermined optical characteristics by one layer (one group of dielectric multilayer films) or may provide the predetermined optical characteristics by two layers. When two or more antireflection layers are provided, the respective antireflection layers may have the same configuration or different configurations.

### <Other Functional Layers>

The optical filter according to the present embodiment may further include a functional layer having other functions as another component, as long as the effect of the present invention is not impaired. Examples of other functional layers include a functional layer that provides absorption by inorganic fine particles or the like that control transmission and absorption of light in a specific wavelength region.

Examples of the inorganic fine particles include indium tin oxides (ITO), antimony-doped tin oxides (ATO), cesium tungstate, and lanthanum boride. The ITO fine particles and the cesium tungstate fine particles have a high visible light transmittance and have light absorbing properties in a wide range of an infrared wavelength region exceeding 1,200 nm, and thus can be used when shielding properties of infrared light are required.

For example, when the optical filter according to the present embodiment is used in an imaging device such as a digital still camera, an imaging device having excellent color reproducibility can be provided. That is, the imaging device according to the present embodiment preferably includes the optical filter, and more specifically includes a solid state image sensor, an imaging lens, and the optical filter. The optical filter can be used, for example, by being disposed between the imaging lens and the solid state image sensor, or by being directly attached to the solid state image sensor, the imaging lens, or the like of the imaging device via an adhesive layer.

### <Method for Manufacturing Optical Filter>

The resin film in the optical filter according to the present embodiment may be formed by dissolving or dispersing a resin or raw material components thereof, a UV dye and an IR dye, and other components blended as necessary in a solvent to prepare a coating solution, applying the coating solution to a support, drying the coating solution, and further curing the coating solution as necessary. When the support in this case is the near-infrared ray absorbing glass used for the optical filter according to the present embodiment, the substrate can be thus directly manufactured. When the support is a peelable support that is used only when the resin film is formed, the substrate can be manufactured by integrating the obtained resin film with the near-infrared ray absorbing glass by thermal press fitting or the like.

The solvent in the coating solution may be a dispersion medium capable of stably dispersing components or a solvent capable of dissolving the components.

The coating solution may contain a surfactant in order to improve voids due to fine bubbles, depressions due to adhesion of foreign substances and the like, and repelling in a drying step.

For the application of the coating solution, for example, a dip coating method, a cast coating method, or a spin coating method can be used.

The curing is performed by, for example, a curing process such as thermal curing or photocuring.

The resin film can also be manufactured into a film shape by extrusion molding. In this case, the substrate can be manufactured by laminating the obtained film-shaped resin film on the near-infrared ray absorbing glass and integrating the resin film and the near-infrared ray absorbing glass by thermal press fitting or the like.

The optical filter according to the present embodiment is obtained by forming the antireflection layer 1 and the antireflection layer 2 formed of the dielectric multilayer film on the outermost layers on both main surface sides of the obtained substrate. Other functional layers may be further formed to form the optical filter as desired.

As described above, the present description discloses the following optical filter and imaging device.

[1] An optical filter including: a substrate, an antireflection layer 1 including a dielectric multilayer film laminated as an outermost layer on one main surface side of the substrate, and an antireflection layer 2 including a dielectric multilayer film laminated as an outermost layer on the other main surface side of the substrate,
in which the substrate includes a near-infrared ray absorbing glass and a resin film laminated on at least one main surface of the near-infrared ray absorbing glass,
the resin film includes a resin, a UV dye having a maximum absorption wavelength in 350 nm to 410 nm in the resin, and an IR dye having a maximum absorption wavelength in 700 nm to 850 nm in the resin, and
the optical filter satisfies all of the following spectral characteristics (i-1) to (i-7):
(i-1) in a spectral transmittance curve at an incident angle of 0 degrees, an average transmittance T_{350-390(0deg)AVE} at a wavelength of 350 nm to 390 nm is 1% or less
(i-2) in a spectral transmittance curve at an incident angle of 0 degrees, a transmittance T_{400(0deg)} at a wavelength of 400 nm is 3% or less
(i-3) in a spectral transmittance curve at an incident angle of 0 degrees, a transmittance T_{400(0deg)} at a wavelength of 400 nm and a transmittance T_{430(0deg)} at a wavelength of 430 nm satisfy the following relation:

$${T}_{430 ( 0 deg )} - {T}_{400 ( 0 deg )} \geq 78 \%$$

(i-4) in a spectral transmittance curve at an incident angle of 0 degrees, an average transmittance T_{430-600(0deg)AVE} at a wavelength of 430 nm to 600 nm is 80% or more
(i-5) when an antireflection layer 1 side is set as an incident direction, an absolute value of a difference between an average reflectance R1_{430-600(5deg)AVE} at a wavelength of 430 nm to 600 nm in a spectral reflectance curve at an incident angle of 5 degrees and an average reflectance R1_{430-600(50deg)AVE} at a wavelength of 430 nm to 600 nm in a spectral reflectance curve at an incident angle of 50 degrees is 4% or less
(i-6) when an antireflection layer 2 side is set as an incident direction, an absolute value of a difference between an average reflectance R2_{430-600(5deg)AVE} at a wavelength of 430 nm to 600 nm in a spectral reflectance curve at an incident angle of 5 degrees and an average reflectance R2_{430-600(50deg)AVE} at a wavelength of 430 nm to 600 nm in a spectral reflectance curve at an incident angle of 50 degrees is 4% or less
(i-7) in a spectral transmittance curve at an incident angle of 0 degrees, an average transmittance T_{750-1100(0deg)AVE} at a wavelength of 750 nm to 1,100 nm is 2% or less.

[2] The optical filter according to [1], further satisfying the following spectral characteristic (i-8):
(i-8) in a spectral transmittance curve at an incident angle of 50 degrees, a transmittance T_{400(50deg)} at a wavelength of 400 nm is 3% or less.

[3] The optical filter according to [1] or [2], further satisfying the following spectral characteristic (i-9):
(i-9) in a spectral transmittance curve at an incident angle of 50 degrees, an average transmittance T_{350-390(50deg)AVE} at a wavelength of 350 nm to 390 nm is 1.5% or less.

[4] The optical filter according to any one of [1] to [3], further satisfying the following spectral characteristics (i-10) and (i-11):
(i-10) a minimum wavelength T_{(0deg)UV50} at which a transmittance is 50% in a wavelength range of 350 nm to 430 nm in a spectral transmittance curve at an incident angle of 0 degrees and a maximum wavelength R1_{(5deg)UV50} at which a reflectance is 50% in a wavelength range of 350 nm to 430 nm in a spectral reflectance curve at an incident angle of 5 degrees when an antireflection layer 1 side is set as an incident direction satisfy the following relation:

$${T}_{( 0 deg ) UV 50} - R {1}_{( 5 deg ) UV 50} > 10 nm$$

(i-11) the T_{(0deg)UV50} and a maximum wavelength R2_{(5deg)UV50} at which a reflectance is 50% in a wavelength range of 350 nm to 430 nm in a spectral reflectance curve at an incident angle of 5 degrees when an antireflection layer 2 side is set as an incident direction satisfy the following relation:

$${T}_{( 0 deg ) UV 50} - R {2}_{( 5 deg ) UV 50} > 10 nm .$$

[5] The optical filter according to [4], further satisfying the following spectral characteristics (i-12) to (i-14):
(i-12) the T_{(0deg)UV50} is in a wavelength range of 400 nm to 430 nm
(i-13) in a spectral transmittance curve at an incident angle of 50 degrees, a minimum wavelength T_{(50deg)UV50} at which a transmittance is 50% in a wavelength range of 350 nm to 430 nm is in a wavelength range of 400 nm to 430 nm
(i-14) an absolute value of a difference between the T_{(0deg)UV50} and the T_{(50deg)UV50} is 4 nm or less.

[6] The optical filter according to any one of [1] to [5], further satisfying the following spectral characteristic (i-15):
(i-15) the average transmittance T_{430-600(0deg)AVE} at a wavelength of 430 nm to 600 nm in a spectral transmittance curve at an incident angle of 0 degrees and an average transmittance T_{430-600(50deg)AVE} at a wavelength of 430 nm to 600 nm in a spectral transmittance curve at an incident angle of 50 degrees satisfy the following relation:

$${T}_{430 - 600 ( 0 deg ) AVE} - {T}_{430 - 600 ( 50 deg ) AVE} \leq 4.5 \% .$$

[7] The optical filter according to any one of [1] to [6], further satisfying the following spectral characteristics (i-16) and (i-17):
(i-16) when an antireflection layer 1 side is set as an incident direction, an average reflectance R1_{750-1100(5deg)AVE} at a wavelength of 750 nm to 1,100 nm in a spectral reflectance curve at an incident angle of 5 degrees is 15% or less
(i-17) when an antireflection layer 2 side is set as an incident direction, an average reflectance R2_{750-1100(5deg)AVE} at a wavelength of 750 nm to 1,100 nm in a spectral reflectance curve at an incident angle of 5 degrees is 15% or less.

[8] The optical filter according to any one of [1] to [7], in which the UV dye includes a merocyanine compound having a maximum absorption wavelength in a wavelength range of 370 nm to 410 nm in the resin.

[9] The optical filter according to [8], in which the UV dye includes the merocyanine compound represented by the following formula (M):

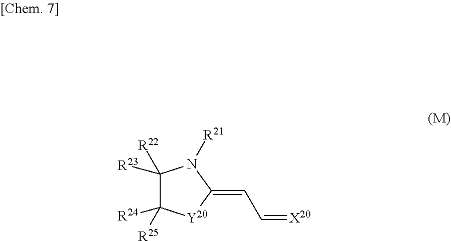

definitions of symbols in the formula (M) are as follows:
R²¹ represents a monovalent hydrocarbon group having 1 to 16 carbon atoms which may have a substituent,
R²² to R²⁵ each independently represent a hydrogen atom, a halogen atom, an alkyl group having 1 to 10 carbon atoms, or an alkoxy group having 1 to 10 carbon atoms,
Y²⁰ represents a methylene group substituted with R²⁶ and R²⁷ or an oxygen atom, and
X²⁰ represents any of divalent groups represented by the following formulae (X1) to (X5):

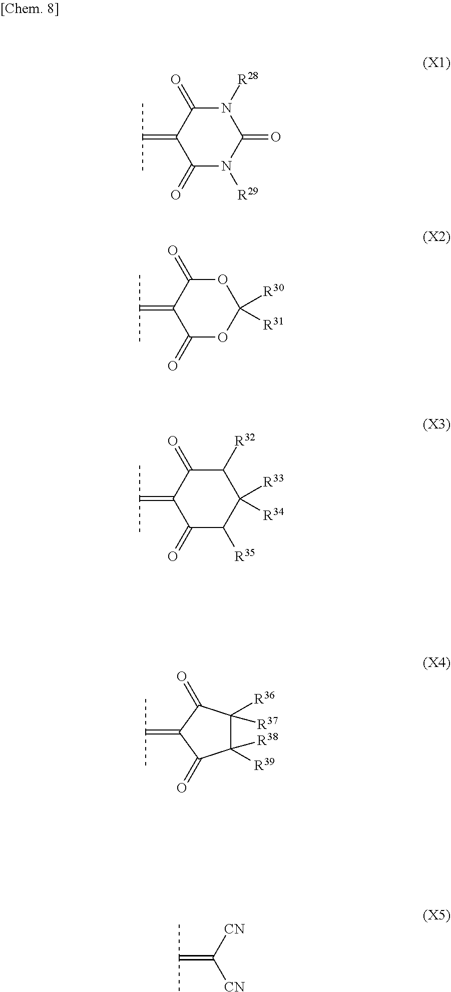

R²⁸ and R²⁹ each independently represent a monovalent hydrocarbon group having 1 to 12 carbon atoms which may have a substituent, and R³⁰ to R³⁹ each independently represent a hydrogen atom or a monovalent hydrocarbon group having 1 to 12 carbon atoms which may have a substituent.

[10] The optical filter according to any one of [1] to [10], in which the UV dye includes a zeromethine compound having a maximum absorption wavelength in a wavelength range of 350 nm to 380 nm in the resin.

[11] The optical filter according to [10], in which the UV dye includes the zeromethine compound represented by the following formula (I):

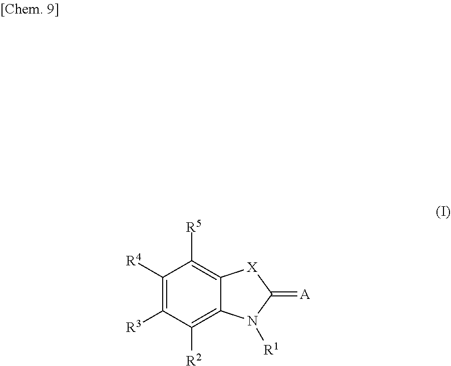

definitions of symbols in the formula (I) are as follows:
X represents an oxygen atom, a sulfur atom, N—R¹⁴, or C—R¹⁵R¹⁶, where R¹⁴ to R¹⁶ each independently represent a hydrogen atom or an alkyl group having 1 to 10 carbon atoms which may have a substituent,
R¹ represents an alkyl group having 1 to 6 carbon atoms which may have a substituent,
R² to R⁵ each independently represent a hydrogen atom, a halogen atom, an alkyl group having 1 to 10 carbon atoms which may have a substituent, an alkoxy group having 1 to 10 carbon atoms which may have a substituent, a nitro group, an amino group, or an amide group, and
A represents any of divalent groups represented by the following formulae (A1) to (A4):

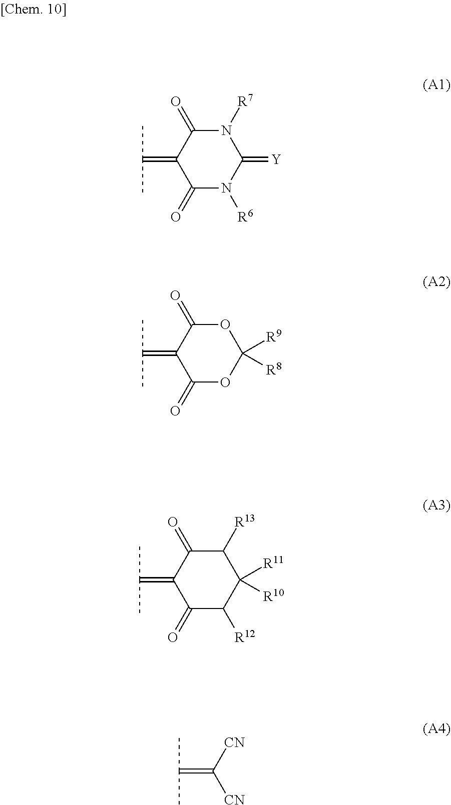

in the formulae (A1) to (A4), Y represents an oxygen atom or a sulfur atom, and R⁶ to R¹³ each independently represent a hydrogen atom or an alkyl group having 1 to 10 carbon atoms which may have a substituent.

[12] The optical filter according to any one of [1] to [11], in which each of the antireflection layer 1 and the antireflection layer 2 has a thickness of 1 μm or less.

[13] The optical filter according to any one of [1] to [12], in which the number of layers of each of the antireflection layer 1 and the antireflection layer 2 is 20 or less.

[14] The optical filter according to any one of [1] to [13], in which the near-infrared ray absorbing glass satisfies the following spectral characteristics (ii-1) and (ii-2):
(ii-1) an average internal transmittance T_{450-600AVE} at a wavelength of 450 nm to 600 nm is 80% or more
(ii-2) an average internal transmittance T_{750-1100AVE} at a wavelength of 750 nm to 1,100 nm is 5% or less.

[15] The optical filter according to any one of [1] to [14], in which the near-infrared ray absorbing glass is a phosphate glass or a fluorophosphate glass containing copper ions.

[16] The optical filter according to any one of [1] to [15], in which the resin film has a thickness of 5 μm or less.

[17] An imaging device including the optical filter according to any one of [1] to [16].

### EXAMPLES

Next, the present invention is described more specifically with reference to examples. For measurement of each optical characteristic, an ultraviolet-visible-near-infrared spectrophotometer (UH-4150 type, manufactured by Hitachi High-Tech Corporation) was used.

The spectral characteristic in the case where an incident angle is not particularly specified is a value measured at an incident angle of 0 degrees (in a direction perpendicular to a main surface).

Dyes used in respective examples are as follows.

Compounds 1 to 8 are UV dyes, and compounds 9 to 11 are IR dyes.

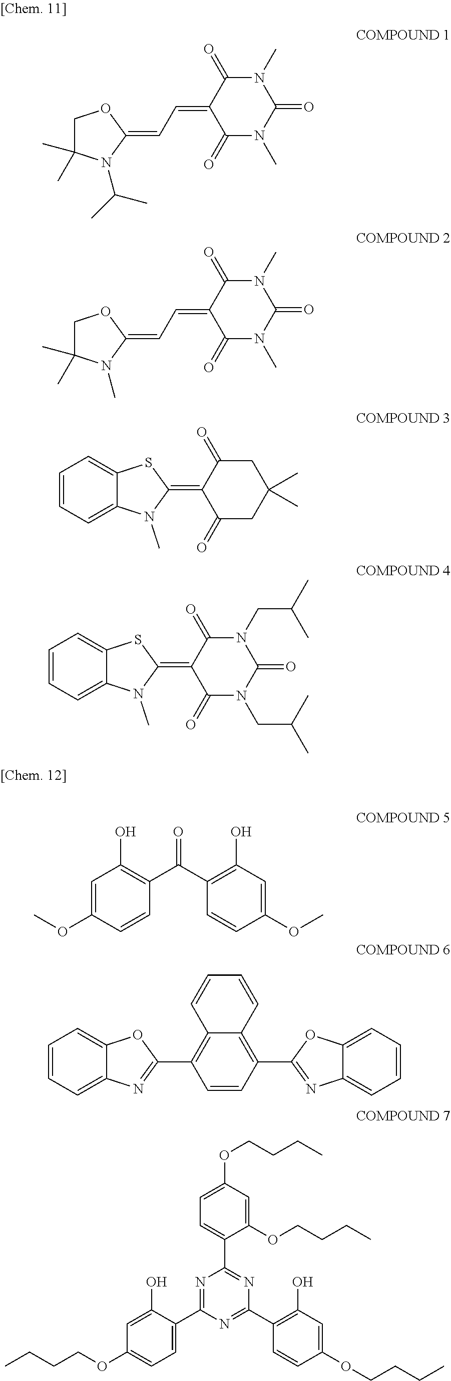

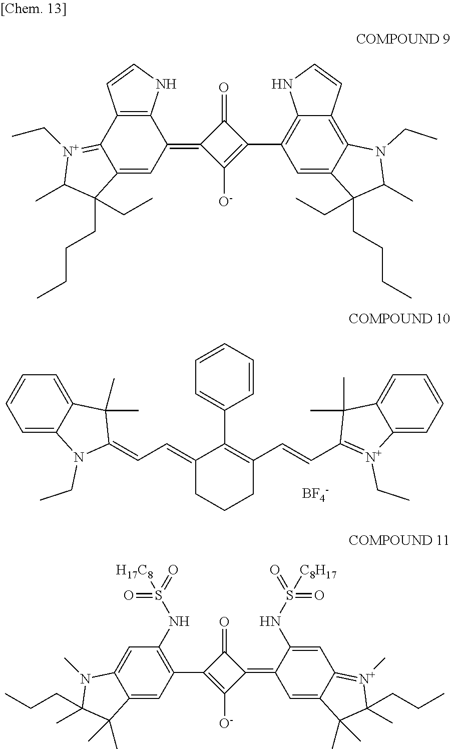

Compounds 1 and 2: synthesized with reference to JP6020746B.

Compounds 3 and 4: synthesized by methods to be shown below, respectively.

Compound 5: D5730 manufactured by Tokyo Chemical Industry Co., Ltd. was used.

Compound 6: B2728 manufactured by Tokyo Chemical Industry Co., Ltd. was used.

Compound 7: Tinuvin 460 manufactured by BASF Japan Ltd. was used.

Compound 8: synthesized with reference to JP6256335B.

Compound 9: synthesized with reference to JP7014272B.

Compound 10: synthesized with reference to Dyes and pigments 73(2007) 344-352.

Compound 11: synthesized with reference to JP6197940B.

### (Synthesis of Compound 3)

### (1) Synthesis of Intermediate 1

2-(methylthio)benzothiazole (25 g) and methyl p-toluenesulfonate (103 g) were placed in a 1 L round-bottom flask and reacted at 130° C. for 5 hours. After the reaction was completed, the mixture was returned to room temperature and filtered to obtain an intermediate 1 (50.5 g) shown in the following scheme.

### (2) Synthesis of Compound 3

Next, the intermediate 1 (5.0 g) obtained above, dimedone (2.1 g), triethylamine (2.8 g), and ethanol (130 mL) were placed in a 1 L round-bottom flask and reacted at room temperature for 3 hours. After the reaction was completed, a solvent was removed, and a precipitated solid was filtered and washed to obtain the compound 3 (2.4 g).

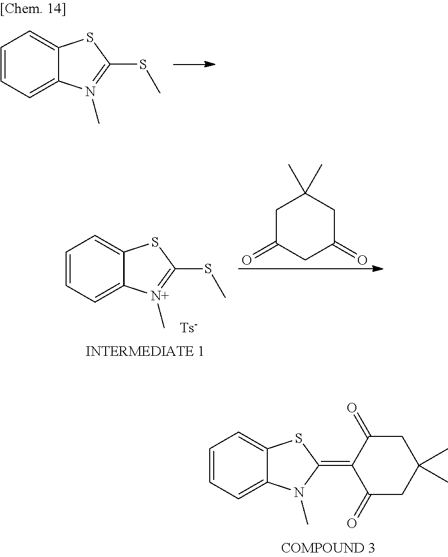

### (Synthesis of Compound 4)

### (1) Synthesis of Intermediate 2

1,1′-carbonyl imidazole (15 g), isobutylamine (15 g), and N,N-dimethylformamide (DMF, 30 mL) were placed in a 1 L round-bottom flask and reacted at 75° C. for 3 hours. After the reaction was completed, the mixture was cooled to room temperature, and acidified by adding 1M aqueous hydrochloric acid, followed by extraction and removal of a solvent to obtain an intermediate 2 (17 g) shown in the following scheme.

### (2) Synthesis of Intermediate 3

Next, the intermediate 2 (17 g) obtained above, malonic acid (10 g), acetic anhydride (33 g), and acetic acid (100 mL) were added to a 1 L round-bottom flask and reacted at 90° C. for 3 hours. After the reaction was completed, the mixture was cooled to room temperature, water was added, and column purification was performed after extraction to obtain an intermediate 3 (21 g) shown in the following scheme.

### (3) Synthesis of Compound 4

Next, the intermediate 1 (5.0 g) obtained in the above synthesis of compound 3, the intermediate 3 (2.1 g) obtained above, triethylamine (2.8 g), and ethanol (130 mL) were placed in a 1 L round-bottom flask and reacted at room temperature for 3 hours. After the reaction was completed, a solvent was removed, and a precipitated solid was filtered and washed to obtain the compound 4 (2.7 g).

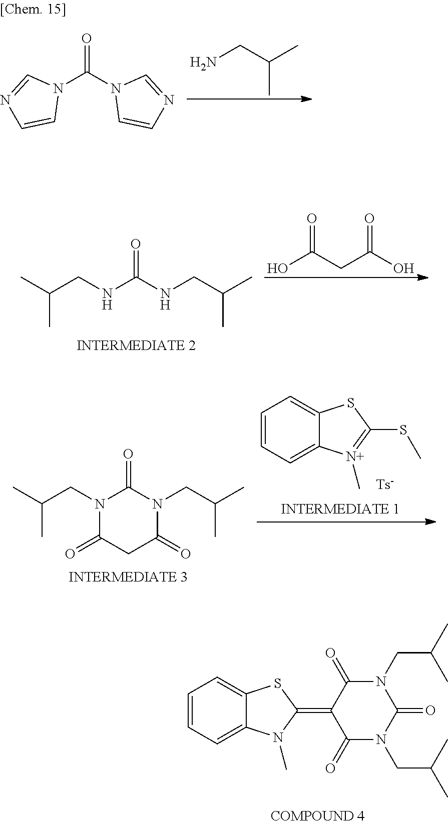

### <Spectral Characteristics of Dye in Resin (in Coating Film)>

A polyimide resin (C-3G30G manufactured by Mitsubishi Gas Chemical Company) was dissolved in an organic solvent (cyclohexanone:γ-butyrolactone=1:1 mass ratio) at a concentration of 8.5 mass %.

The compound 1 was added to the solution of the polyimide resin prepared above in an amount of 7.0 parts by mass with respect to 100 parts by mass of the resin, and the mixture was stirred for 2 hours while being heated to 50° C. A dye-containing resin solution was spin-coated onto a glass substrate (alkaline glass, D263 manufactured by schott) to obtain a coating film having a film thickness of 1 km.

For the compounds 2 to 11, coating films were prepared in the same manner.

Transmission spectroscopy (incident angle of 0 degrees) and reflection spectroscopy (incident angle of 5 degrees) in a wavelength range of 350 nm to 1,200 nm were measured for each of the obtained coating-film-equipped glass substrates using a spectrophotometer. A maximum absorption wavelength was calculated based on a spectral internal transmittance curve obtained using spectral transmittance curves and spectral reflectance curves.

Results are shown in Table 3 below.

TABLE 3

| | Maximum absorption wavelength in resin |
|---|---|
| Compound 1 | 400 nm |
| Compound 2 | 397 nm |
| Compound 3 | 365 nm |
| Compound 4 | 365 nm |
| Compound 5 | 353 nm |
| Compound 6 | 376 nm |
| Compound 7 | 351 nm |
| Compound 8 | 372 nm |
| Compound 9 | 752 nm |
| Compound 10 | 773 nm |
| Compound 11 | 706 nm |

### <Spectral Characteristics of Phosphate Glass>

As the near-infrared ray absorbing glass, a phosphate glass having a composition shown in the following table was prepared.

With respect to the phosphate glass, a spectral transmittance curve in the wavelength range of 350 nm to 1,200 nm was measured using an ultraviolet-visible spectrophotometer.

Spectral characteristics shown in Table 4 below were calculated based on the obtained data of the spectral characteristics. The spectral characteristics shown in Table 4 below were evaluated in terms of internal transmittance in order to avoid an influence of reflection at an air interface and a glass interface.

A spectral transmittance curve of the phosphate glass is illustrated in FIG. 2.

TABLE 4

| | | |
|---|---|---|
| Glass | Type | Phosphate glass |
| | Thickness (mm) | 0.28 |
| Composition (mass %) | P₂O₅ | 68 |
| | Al₂O₃ | 11 |
| | Na₂O | 3 |
| | K₂O | 6 |
| | MgO | 4 |
| | CuO | 8 |
| | Total | 100 |
| Spectral | 450-600 nm average internal | 84.8 |
| characteristics | transmittance (%) | |
| | 750-1100 nm average internal | 0.9 |
| | transmittance (%) | |

As described above, it is understood that the used near-infrared ray absorbing glass has a high transmittance in a visible light region and is excellent in light-shielding properties in a near-infrared ray region.

### <Spectral Characteristics of Optical Filter>

### Example 1-1

A polyimide resin (C-3G30G manufactured by Mitsubishi Gas Chemical Company) was dissolved in an organic solvent (cyclohexanone:γ-butyrolactone=1:1 mass ratio) at a concentration of 8.5 mass %. To the solution of the polyimide resin, 5.0 parts by mass of the compound 1, 4.7 parts by mass of the compound 3, 1.5 parts by mass of the compound 8, and 1.6 parts by mass of the compound 9 were added with respect to 100 parts by mass of the resin, and the mixture was stirred for 2 hours while being heated to 50° C. A dye-containing resin solution was spin-coated on the above phosphate glass having a thickness of 0.28 mm to obtain a glass substrate having a resin film with a film thickness of 1.6 μm.

An optical filter of Example 1-1 was obtained by forming, on a surface (B surface) of the resin film-equipped glass substrate on which the resin film is present, an antireflection layer formed of a dielectric multilayer film having a total thickness of 0.37 μm and the number of layers of 7 in which SiO₂ and TiO₂ were alternately laminated, and forming, on a glass surface (A surface) on which the resin film is absent, an antireflection layer formed of a dielectric multilayer film having a total thickness of 0.81 μm and the number of layers of 15 in which SiO₂ and TiO₂ were alternately laminated.

### Examples 1-2 to 1-5

Optical filters were obtained in the same manner as in Example 1-1 except that the film thickness of the resin film and a type and a content of a dye compound were changed as shown in Table 5 below.

### Example 1-6

An optical filter was obtained in the same manner as in Example 1-1 except that the dielectric multilayer film formed on the B surface was changed to an antireflection layer having a total thickness of 0.81 μm and the number of layers of 15.

### Example 1-7

An optical filter was obtained in the same manner as in Example 1-1 except that the dielectric multilayer film formed on the A surface was changed to a reflection layer having a total thickness of 5.0 μm and the number of layers of 42 in which SiO₂ and TiO₂ were alternately laminated.

### Examples 1-8 to 1-11

Optical filters were obtained in the same manner as in Example 1-1 except that the film thickness of the resin film and a type and a content of a dye compound were changed as shown in Table 5 below.

### Example 1-12

An optical filter was obtained in the same manner as in Example 1-1 except that a borosilicate glass (D263 alkaline glass manufactured by SCHOTT) was used instead of the phosphate glass.

TABLE 5

| Optical filter | | | Example 1-1 | Example 1-2 | Example 1-3 | Example 1-4 | Example 1-5 | Example 1-6 |
|---|---|---|---|---|---|---|---|---|
| Multilayer | A surface | | Antireflection | Antireflection | Antireflection | Antireflection | Antireflection | Antireflection |
| film | | | layer | layer | layer | layer | layer | layer |
| | | | 15 layers | 15 layers | 15 layers | 15 layers | 15 layers | 15 layers |
| Glass | | | Phosphate | Phosphate | Phosphate | Phosphate | Phosphate | Phosphate |
| | | | glass | glass | glass | glass | glass | glass |
| Resin film | UV | Compound | 5 | | 5 | | | 5 |
| (absorption | dye | 1 (λmax: | | | | | | |
| layer) | | 400 nm) | | | | | | |
| | | Compound | | 4.4 | | 4.7 | 4.7 | |
| | | 2 (λmax: | | | | | | |
| | | 397 nm) | | | | | | |
| | | Compound | 4.7 | 4.7 | | | 4.7 | 4.7 |
| | | 3 (λmax: | | | | | | |
| | | 365 nm) | | | | | | |
| | | Compound | | | 4.7 | 4.7 | | |
| | | 4 (λmax: | | | | | | |
| | | 365 nm) | | | | | | |
| | | Compound | | | | | | |
| | | 5 (λmax: | | | | | | |
| | | 353 nm) | | | | | | |
| | | Compound | | | | | | |
| | | 6 (λmax: | | | | | | |
| | | 376 nm) | | | | | | |
| | | Compound | | | | | | |
| | | 7 (λmax: | | | | | | |
| | | 351 nm) | | | | | | |
| | | Compound | | | | | | |
| | | 8 (λmax: | | | | | | |
| | | 372 nm) | | | | | | |
| | IR | Compound | 1.5 | 1.5 | 1.5 | 1.5 | 1.9 | 1.5 |
| | dye | 9 (λmax: | | | | | | |
| | | 752 nm) | | | | | | |
| | | Compound | 1.6 | 1.6 | 1.6 | 1.6 | | 1.6 |
| | | 10 (λmax: | | | | | | |
| | | 773 nm) | | | | | | |
| | | Compound | | | | | 3.4 | |
| | | 11 (λmax: | | | | | | |
| | | 706 nm) | | | | | | |
| | Film thickness | | 1.6 | 1.6 | 1.6 | 1.6 | 1.6 | 1.6 |
| | (μm) | | | | | | | |
| Multilayer | B surface | | Antireflection | Antireflection | Antireflection | Antireflection | Antireflection | Antireflection |
| film | | | layer | layer | layer | layer | layer | layer |
| | | | 7 layers | 7 layers | 7 layers | 7 layers | 7 layers | 15 layers |
| Optical filter | | | Example 1-7 | Example 1-8 | Example 1-9 | Example 1-10 | Example 1-11 | Example 1-12 |
| Multilayer | A surface | | Reflection | Antireflection | Antireflection | Antireflection | Antireflection | Antireflection |
| film | | | layer | layer | layer | layer | layer | layer |
| | | | 42 layers | 15 layers | 15 layers | 15 layers | 15 layers | 15 layers |
| Glass | | | Phosphate | Phosphate | Phosphate | Phosphate | Phosphate | Borosilicate |
| | | | glass | glass | glass | glass | glass | glass |
| Resin film | UV | Compound | 5 | | | | | 5 |
| (absorption | dye | 1 (λmax: | | | | | | |
| layer) | | 400 nm) | | | | | | |
| | | Compound | | | | | | |
| | | 2 (λmax: | | | | | | |
| | | 397 nm) | | | | | | |
| | | Compound | 4.7 | | | | | 4.7 |
| | | 3 (λmax: | | | | | | |
| | | 365 nm) | | | | | | |
| | | Compound | | | | | | |
| | | 4 (λmax: | | | | | | |
| | | 365 nm) | | | | | | |
| | | Compound | | 12 | | | | |
| | | 5 (λmax: | | | | | | |
| | | 353 nm) | | | | | | |
| | | Compound | | | 10 | | | |
| | | 6 (λmax: | | | | | | |
| | | 376 nm) | | | | | | |
| | | Compound | | | | 10 | | |
| | | 7 (λmax: | | | | | | |
| | | 351 nm) | | | | | | |
| | | Compound | | | | | 10 | |
| | | 8 (λmax: | | | | | | |
| | | 372 nm) | | | | | | |
| | IR | Compound | 1.5 | 1.2 | 1.5 | 1.5 | 1.9 | 1.5 |
| | dye | 9 (λmax: | | | | | | |
| | | 752 nm) | | | | | | |
| | | Compound | 1.6 | 1.3 | 1.6 | 1.6 | | 1.6 |
| | | 10 (λmax: | | | | | | |
| | | 773 nm) | | | | | | |
| | | Compound | | | | | 3.4 | |
| | | 11 (λmax: | | | | | | |
| | | 706 nm) | | | | | | |

| | | | | | | | |
|---|---|---|---|---|---|---|---|
| | Film thickness | 1.6 | 2 | 1.6 | 1.6 | 1.6 | 1.6 |
| | (μm) | | | | | | |
| Multilayer | B surface | Antireflection | Antireflection | Antireflection | Antireflection | Antireflection | Antireflection |
| film | | layer | layer | layer | layer | layer | layer |

| | | | | | |
|---|---|---|---|---|---|
| 7 layers | 7 layers | 7 layers | 7 layers | 7 layers | 7 layers |

With respect to the respective optical filters, spectral transmittance curves at an incident angle of 0 degrees and an incident angle of 50 degrees and spectral reflectance curves at an incident angle of 5 degrees and an incident angle of 50 degrees in the wavelength range of 350 nm to 1,200 nm were measured using an ultraviolet-visible spectrophotometer.

A configuration of the optical filter was dielectric multilayer film 1 (A surface)/near-infrared ray absorbing glass/resin film/dielectric multilayer film 2 (B surface).

Respective characteristics shown in Table 6 below were calculated based on the obtained data of the spectral characteristics.

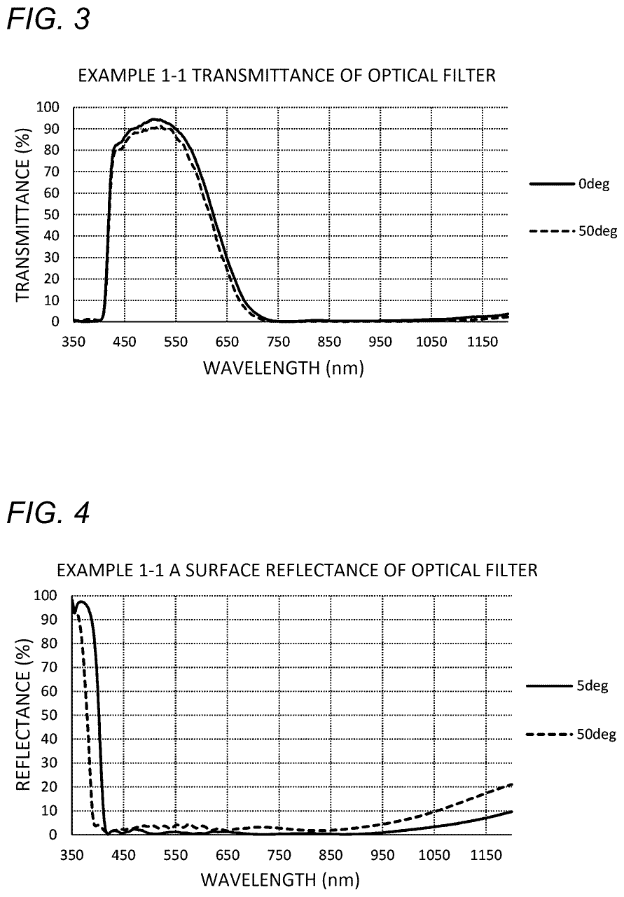

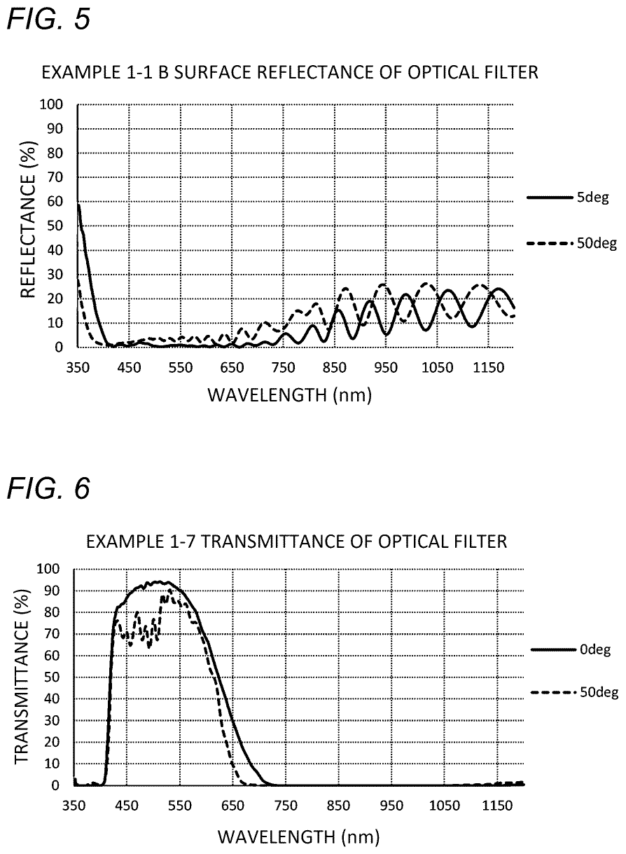

Spectral transmittance curves, spectral reflectance curves (A surface side), and spectral reflectance curves (B surface side) of the optical filter of Example 1-1 are shown in FIGS. 3 to 5, respectively.

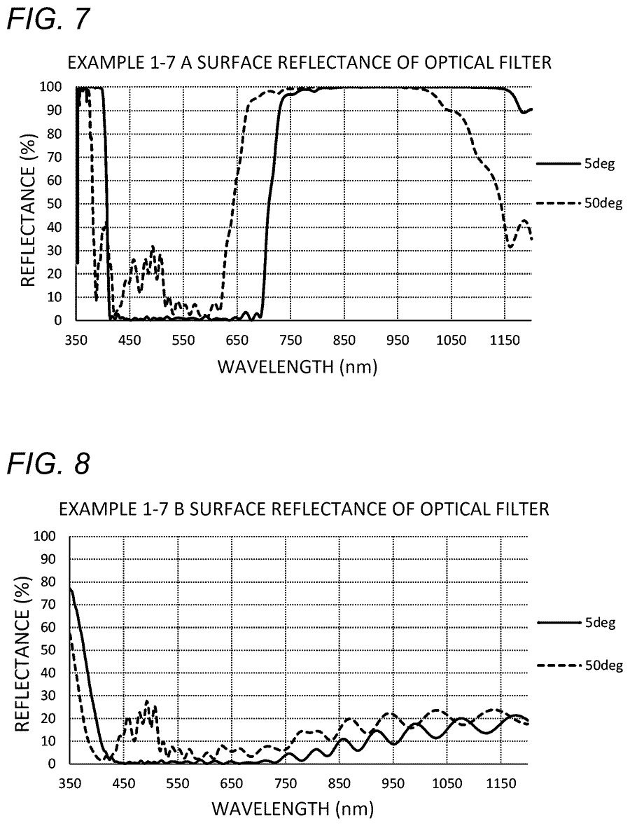

Spectral transmittance curves, spectral reflectance curves (A surface side), and spectral reflectance curves (B surface side) of the optical filter of Example 1-7 are shown in FIGS. 6 to 8, respectively.

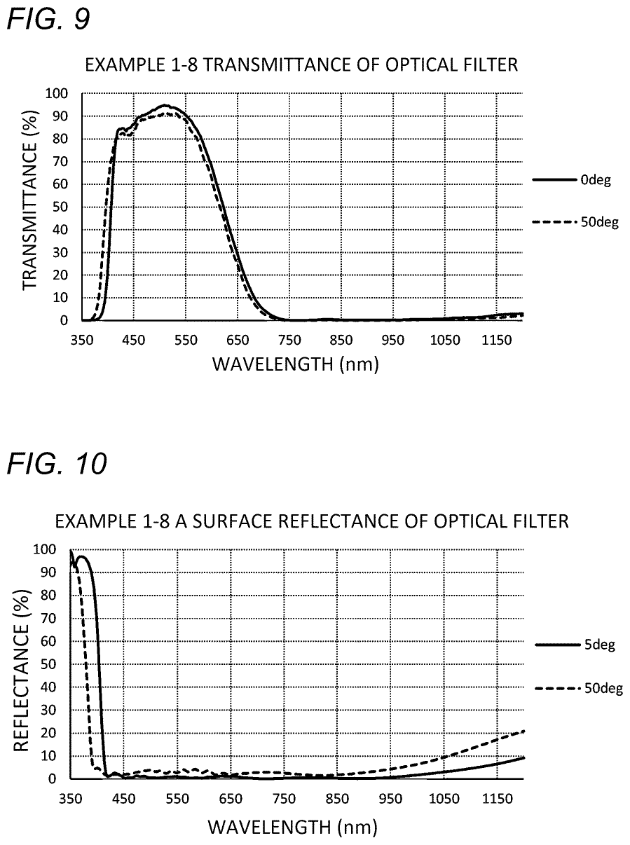

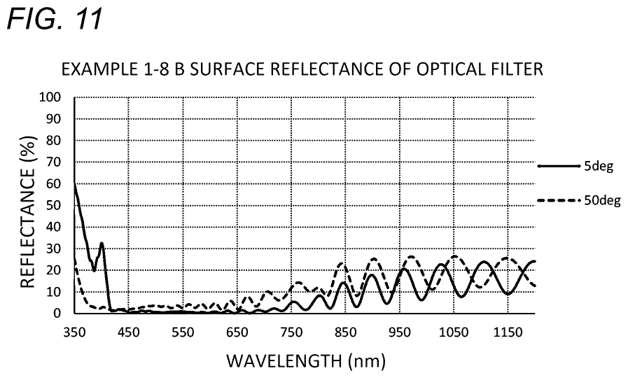

Spectral transmittance curves, spectral reflectance curves (A surface side), and spectral reflectance curves (B surface side) of the optical filter of Example 1-8 are shown in FIGS. 9 to 11, respectively.

Examples 1-1 to 1-6 are inventive examples, and Examples 1-7 to 1-12 are comparative examples.

TABLE 6

| | Example | Example | Example | Example | Example | Example |
|---|---|---|---|---|---|---|
| Spectral characteristics of optical filter | 1-1 | 1-2 | 1-3 | 1-4 | 1-5 | 1-6 |
| 350-390 nm (0 deg) average transmittance (%) | 0.2 | 0.2 | 0.2 | 0.2 | 0.2 | 0.0 |
| 400 nm (0 deg) transmittance (%) | 0.4 | 0.9 | 0.4 | 1.0 | 0.9 | 0.4 |
| \|430 nm (0 deg) transmittance − 400 nm (0 deg) | 80.8 | 82.1 | 80.9 | 82.4 | 79.9 | 80.2 |
| transmittance\| (%) | | | | | | |
| 430-600 nm (0 deg) average transmittance (%) | 87.6 | 87.9 | 87.8 | 87.8 | 87.4 | 86.6 |
| R1, 430-600 nm (5 deg) average reflectance (%) | 1.0 | 0.9 | 0.8 | 0.8 | 0.9 | 1.7 |
| R1, 430-600 nm (50 deg) average reflectance (%) | 3.1 | 3.2 | 3.0 | 3.1 | 3.1 | 4.0 |
| \|R1, 430-600 nm (5 deg) average reflectance − | 2.1 | 2.3 | 2.3 | 2.2 | 2.2 | 2.3 |
| R1, 430-600 nm (50 deg) average reflectance\| (%) | | | | | | |
| R2, 430-600 nm (5 deg) average reflectance (%) | 0.9 | 0.8 | 0.7 | 0.7 | 0.8 | 1.8 |
| R2, 430-600 nm (50 deg) average reflectance (%) | 3.0 | 3.2 | 3.0 | 3.0 | 3.0 | 4.3 |
| \| R2, 430-600 nm (5 deg) average reflectance − | 2.2 | 2.4 | 2.3 | 2.3 | 2.3 | 2.5 |
| R2, 430-600 nm (50 deg) average reflectance\| (%) | | | | | | |
| 750-1100 nm (0 deg) average transmittance (%) | 0.6 | 0.6 | 0.6 | 0.6 | 0.7 | 0.7 |
| 400 nm (50 deg) transmittance (%) | 0.6 | 1.6 | 0.6 | 1.7 | 1.6 | 0.6 |
| 350-390 nm (50 deg) average transmittance (%) | 0.8 | 0.9 | 1.0 | 1.0 | 1.0 | 0.8 |
| Wavelength T(0 deg)UV50 (nm) | 419.0 | 415.7 | 418.9 | 415.6 | 416.2 | 419.1 |
| Wavelength R1(5 deg)UV50 (nm) | 402.3 | 403.7 | 402.6 | 403.4 | 403.2 | 404.4 |
| Wavelength R2(5 deg)UV50 (nm) | 356.4 | 357.4 | 357.1 | 356.5 | 357.2 | 389.7 |
| \|Wavelength T(0 deg)UV50 − wavelength | 16.6 | 11.9 | 16.3 | 12.2 | 13.0 | 14.7 |
| R1(5 deg)UV50\| (nm) | | | | | | |
| \|Wavelength T(0 deg)UV50 − wavelength | 62.5 | 58.2 | 61.8 | 59.1 | 59.0 | 29.4 |
| R2(5 deg)UV50\| (nm) | | | | | | |
| Wavelength T(50 deg)UV50 (nm) | 419.8 | 416.2 | 419.7 | 416.1 | 416.9 | 419.9 |
| \|Wavelength T(0 deg)UV50 − wavelength | 0.9 | 0.5 | 0.8 | 0.5 | 0.7 | 0.8 |
| T(50 deg)UV50\| (nm) | | | | | | |
| 430-600 nm (50 deg) average transmittance (%) | 84.0 | 84.0 | 84.1 | 84.0 | 83.6 | 82.9 |
| \|430-600 nm (0 deg) average transmittance − | 3.6 | 4.0 | 3.7 | 3.8 | 3.8 | 3.7 |
| 430-600 nm (50 deg) average transmittance \| (%) | | | | | | |
| R1, 750-1100 nm (5 deg) average reflectance (%) | 1.4 | 1.4 | 1.5 | 1.4 | 1.4 | 1.3 |
| R2, 750-1100 nm (5 deg) average reflectance (%) | 11.6 | 11.9 | 12.0 | 12.0 | 11.8 | 3.3 |
| 430-600 nm (0 deg) minimum transmittance (%) | 67.7 | 68.2 | 67.7 | 68.1 | 65.0 | 68.0 |
| 430-600 nm (0 deg) maximum transmittance (%) | 94.4 | 94.5 | 94.4 | 94.5 | 94.6 | 94.4 |
| 750-1100 nm (0 deg) maximum transmittance (%) | 1.6 | 1.6 | 1.6 | 1.5 | 1.6 | 1.8 |
| | Example | Example | Example | Example | Example | Example |
| Spectral characteristics of optical filter | 1-7 | 1-8 | 1-9 | 1-10 | 1-11 | 1-12 |
| 350-390 nm (0 deg) average transmittance (%) | 0.1 | 0.6 | 0.1 | 1.4 | 0.1 | 0.2 |
| 400 nm (0 deg) transmittance (%) | 0.0 | 22.8 | 7.9 | 32.6 | 5.5 | 0.4 |
| \|430 nm (0 deg) transmittance − 400 nm (0 deg) | 80.0 | 61.9 | 76.1 | 50.7 | 73.7 | 86.2 |
| transmittance\| (%) | | | | | | |
| 430-600 nm (0 deg) average transmittance (%) | 87.7 | 88.0 | 88.1 | 88.0 | 87.4 | 94.4 |
| R1, 430-600 nm (5 deg) average reflectance (%) | 0.8 | 0.9 | 0.9 | 0.9 | 0.9 | 0.9 |
| R1, 430-600 nm (50 deg) average reflectance (%) | 12.3 | 3.0 | 3.3 | 3.1 | 3.1 | 3.5 |
| \|R1, 430-600 nm (5 deg) average reflectance − | 11.4 | 2.1 | 2.4 | 2.1 | 2.2 | 2.6 |
| R1, 430-600 nm (50 deg) average reflectance\|(%) | | | | | | |
| R2, 430-600 nm (5 deg) average reflectance (%) | 0.8 | 0.8 | 0.8 | 0.8 | 0.8 | 0.8 |
| R2, 430-600 nm (50 deg) average reflectance (%) | 10.7 | 3.0 | 3.3 | 3.0 | 3.1 | 3.4 |
| \| R2, 430-600 nm (5 deg) average reflectance − | 9.9 | 2.2 | 2.6 | 2.2 | 2.3 | 2.6 |
| R2, 430-600 nm (50 deg) average reflectance\| (%) | | | | | | |
| 750-1100 nm (0 deg) average transmittance (%) | 0.0 | 0.5 | 0.6 | 0.6 | 0.7 | 72.2 |
| 400 nm (50 deg) transmittance (%) | 0.4 | 58.8 | 21.2 | 75.3 | 12.5 | 0.7 |
| 350-390 nm (50 deg) average transmittance (%) | 0.4 | 5.2 | 0.8 | 12.3 | 0.6 | 1.0 |
| Wavelength T(0 deg)UV50 (nm) | 419.3 | 406.6 | 410.8 | 403.9 | 414.1 | 418.3 |
| Wavelength R1(5 deg)UV50 (nm) | 407.7 | 403.9 | 402.0 | 401.8 | 403.3 | 402.6 |
| Wavelength R2(5 deg)UV50 (nm) | 376.7 | 358.7 | 356.5 | 356.3 | 357.4 | 356.0 |
| \|Wavelength T(0 deg)UV50 − wavelength | 11.6 | 2.7 | 8.8 | 2.0 | 10.9 | 15.7 |
| R1(5 deg)UV50\| (nm) | | | | | | |
| \|Wavelength T(0 deg)UV50 − wavelength | 42.6 | 47.9 | 54.2 | 47.5 | 56.8 | 62.3 |
| R2(5 deg)UV50\| (nm) | | | | | | |
| Wavelength T(50 deg)UV50 (nm) | 420.2 | 396.5 | 408.3 | 388.2 | 414.6 | 419.0 |
| \|Wavelength T(0 deg)UV50 − wavelength | 0.9 | 10.1 | 2.5 | 15.6 | 0.5 | 0.8 |
| T(50 deg)UV50\| (nm) | | | | | | |
| 430-600 nm (50 deg) average transmittance (%) | 75.6 | 84.7 | 84.2 | 84.2 | 83.7 | 91.3 |
| \|430-600 nm (0 deg) average transmittance − | 12.1 | 3.3 | 3.9 | 3.7 | 3.8 | 3.1 |
| 430-600 nm (50 deg) average transmittance \| (%) | | | | | | |
| R1, 750-1100 nm (5 deg) average reflectance (%) | 99.7 | 1.3 | 1.5 | 1.4 | 1.4 | 12.2 |
| R2, 750-1100 nm (5 deg) average reflectance (%) | 10.8 | 11.1 | 11.1 | 11.5 | 11.6 | 12.9 |
| 430-600 nm (0 deg) minimum transmittance (%) | 67.8 | 67.7 | 68.4 | 68.1 | 65.4 | 86.7 |
| 430-600 nm (0 deg) maximum transmittance (%) | 94.1 | 94.8 | 94.7 | 94.7 | 94.7 | 97.6 |
| 750-1100 nm (0 deg) maximum transmittance (%) | 0.0 | 1.3 | 1.8 | 1.6 | 1.5 | 95.5 |

It is understood that the optical filters of Examples 1-1 to 1-6 are filters having a high transmittance in the visible light region, high shielding properties in the near-infrared region extending over a wide range of 700 nm to 1,100 nm, and high shielding properties in the near-ultraviolet light region, and in which ripple generation is prevented since a change in transmittance of the visible light is low even at a high incident angle. In addition, it is understood that the optical filters can sufficiently take in necessary visible light as a change in transmittance from a light-shielding region of ultraviolet light to a transmission region of visible light is steep.

Since the optical filter of Example 1-7 used the reflection layer, a spectral variation at a high incident angle is large, and variations of a visible reflectance and a visible transmittance are large.

In the optical filters of Examples 1-8 to 1-11, absorption characteristics of the UV dye were insufficient, a light leakage occurred in a near-ultraviolet region for which light should be shielded, and oblique incidence characteristics were poor.

Since the optical filter of Example 1-12 used the glass having no absorption (borosilicate glass), light-shielding properties in the near-infrared region were low.

### <Light Resistance of Optical Filter>

In order to evaluate the light resistance of the dye, the following tests were performed.

### Example 2-1

A polyimide resin (C-3G30G manufactured by Mitsubishi Gas Chemical Company) was dissolved in an organic solvent (cyclohexanone:γ-butyrolactone=1:1 mass ratio) at a concentration of 8.5 mass %. To the solution of the polyimide resin, 7.5 parts by mass of the compound 2 and 7.0 parts by mass of the compound 11 were added with respect to 100 parts by mass of the resin, and the mixture was stirred for 2 hours while being heated to 50° C.

A dye-containing resin solution was spin-coated on a borosilicate glass (D263 glass manufactured by SCHOTT) to obtain a glass substrate having a resin film with a film thickness of 1.3 μm.

An antireflection layer formed of a dielectric multilayer film having a total thickness of 0.37 μm and the number of layers of 7 in which SiO₂ and TiO₂ were alternately laminated was formed on a resin film surface of the resin film-equipped glass substrate to obtain a filter for light resistance evaluation.

### Examples 2-2 to 2-4

Filters for light resistance evaluation were obtained in the same manner as in Example 2-1 except that a type and a content of a dye compound in the resin film were as shown in Table 7.

Each of the above filters was irradiated with light from an antireflection layer side, and a light resistance test was performed using a super xenon weather meter (manufactured by Suga Test Instruments Co., Ltd.).

The emitted light has an integral of light of 80,000 J/mm² at a wavelength band of 300 nm to 2,450 nm. Each variation rate in absorbance at 370 nm, 400 nm, 700 nm, or 750 nm before and after the light resistance test was calculated, and the light resistance of the dye was evaluated. Results are shown in Table 7 below.

Variation rate (%)=100−(absorbance at each wavelength after test/absorbance at each wavelength before test×100)

Examples 2-1 to 2-4 are reference examples.

TABLE 7

| | | Exam- | Exam- | Exam- | Exam- |
|---|---|---|---|---|---|
| | | ple | ple | ple | ple |
| | | 2-1 | 2-2 | 2-3 | 2-4 |
| Content of | Compound 2 (λmax: | 7.5 | — | 5 | — |
| dye (parts | 397 nm) | | | | |
| by mass) | Compound 3 (λmax: | — | 8 | — | — |
| | 365 nm) | | | | |
| | Compound 6 (λmax: | — | — | 5 | — |
| | 376 nm) | | | | |
| | Compound 8 (λmax: | — | — | — | 8 |
| | 372 nm) | | | | |
| | Compound 9 (λmax: | — | 3 | — | 3 |
| | 752 nm) | | | | |
| | Compound 11 (λmax: | 7 | 5.5 | 7.5 | 5.5 |
| | 706 nm) | | | | |
| Evaluation | Variation rate at | 5% | 4% | 1% | 37% |
| | 370 nm | | | | |
| | Variation rate at | 0% | 4% | 7% | 21% |
| | 400 nm | | | | |
| | Variation rate at | 12% | 16% | 38% | 12% |
| | 700 nm | | | | |
| | Variation rate at | 5% | 11% | 41% | 10% |
| | 750 nm | | | | |

In the above results, the smaller the variation rate is, the less likely the dye compound is photodegraded, and the better the light resistance is. The variation rate is preferably 20% or less.

Based on the results of Examples 2-1 and 2-2, it is understood that the compound 2 and the compound 3 are excellent in durability of the UV dye itself and do not affect the light resistance of the IR dye even when being used in combination with the IR dye.

Based on the results of Examples 2-1 and 2-3, it is understood that by newly adding the compound 6, the variation rate in an IR region was increased, and thus the photodegradation of the IR dye was promoted.

Based on the results of Example 2-4, it is understood that the compound 8 does not affect the light resistance of the IR dye, but the variation rate in a UV region was large, and thus the photodegradation of itself was promoted.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2022-138362) filed on Aug. 31, 2022, the content of which is incorporated herein by reference.

### INDUSTRIAL APPLICABILITY

The optical filter according to the present invention has spectral characteristics in which a ripple and stray light in the visible light region is prevented even at a high incident angle, and the transmittance in the visible light region and the shielding properties in the near-infrared light region are excellent. In recent years, the optical filter is useful for applications of imaging devices such as cameras and sensors for transport machines, for which high performance has been achieved.

### REFERENCE SIGNS LIST

1B: optical filter
10: substrate
11: near-infrared ray absorbing glass
12: resin film
20A, 20B: dielectric multilayer film

1. An optical filter comprising:
a substrate,
an antireflection layer 1 comprising a dielectric multilayer film laminated on one main surface side of the substrate, and
an antireflection layer 2 comprising a dielectric multilayer film laminated on the other main surface side of the substrate,
wherein the substrate comprises a near-infrared ray absorbing glass and a resin film,
the resin film comprises a resin, a UV dye having a maximum absorption wavelength in 350 nm to 410 nm in the resin, and an IR dye having a maximum absorption wavelength in 700 nm to 850 nm in the resin, and
the optical filter satisfies all of the following spectral characteristics (i-1) to (i-7):
(i-1) in a spectral transmittance curve at an incident angle of 0 degrees, an average transmittance T_{350-390(0deg)AVE} at a wavelength of 350 nm to 390 nm is 1% or less
(i-2) in a spectral transmittance curve at an incident angle of 0 degrees, a transmittance T_{400(0deg)} at a wavelength of 400 nm is 3% or less
(i-3) in a spectral transmittance curve at an incident angle of 0 degrees, a transmittance T_{400(0deg)} at a wavelength of 400 nm and a transmittance T_{430(0deg)} at a wavelength of 430 nm satisfy the following relation:
$${T}_{430 ( 0 dcg )} - {T}_{400 ( 0 deg )} \geq 78 \% .$$
(i-4) in a spectral transmittance curve at an incident angle of 0 degrees, an average transmittance T_{430-600(0deg)AVE} at a wavelength of 430 nm to 600 nm is 80% or more
(i-5) when an antireflection layer 1 side is set as an incident direction, an absolute value of a difference between an average reflectance R1_{430-600(5deg)AVE} at a wavelength of 430 nm to 600 nm in a spectral reflectance curve at an incident angle of 5 degrees and an average reflectance R1_{430-600(50deg)AVE} at a wavelength of 430 nm to 600 nm in a spectral reflectance curve at an incident angle of 50 degrees is 4% or less
(i-6) when an antireflection layer 2 side is set as an incident direction, an absolute value of a difference between an average reflectance R2_{430-600(5deg)AVE} at a wavelength of 430 nm to 600 nm in a spectral reflectance curve at an incident angle of 5 degrees and an average reflectance R2_{430-600(50deg)AVE} at a wavelength of 430 nm to 600 nm in a spectral reflectance curve at an incident angle of 50 degrees is 4% or less
(i-7) in a spectral transmittance curve at an incident angle of 0 degrees, an average transmittance T_{750-1100(0deg)AVE} at a wavelength of 750 nm to 1,100 nm is 2% or less.

2. The optical filter according to claim 1, further satisfying the following spectral characteristic (i-8):
(i-8) in a spectral transmittance curve at an incident angle of 50 degrees, a transmittance T_{400(50deg)} at a wavelength of 400 nm is 3% or less.

3. The optical filter according to claim 1, further satisfying the following spectral characteristic (i-9):
(i-9) in a spectral transmittance curve at an incident angle of 50 degrees, an average transmittance T_{350-390(50deg)AVE} at a wavelength of 350 nm to 390 nm is 1.5% or less.

4. The optical filter according to claim 1, further satisfying the following spectral characteristics (i-10) and (i-11):
(i-10) a minimum wavelength T_{(0deg)UV50} at which a transmittance is 50% in a wavelength range of 350 nm to 430 nm in a spectral transmittance curve at an incident angle of 0 degrees and a maximum wavelength R1_{(5deg)UV50} at which a reflectance is 50% in a wavelength range of 350 nm to 430 nm in a spectral reflectance curve at an incident angle of 5 degrees when an antireflection layer 1 side is set as an incident direction satisfy the following relation:
$${T}_{( 0 deg ) UV 50} - R {1}_{( 5 deg ) UV 50} > 10 nm .$$
(i-11) the T_{(0deg)UV50} and a maximum wavelength R2_{(5deg)UV50} at which a reflectance is 50% in a wavelength range of 350 nm to 430 nm in a spectral reflectance curve at an incident angle of 5 degrees when an antireflection layer 2 side is set as an incident direction satisfy the following relation:
$${T}_{( 0 deg ) UV 50} - R {2}_{( 5 deg ) UV 50} > 10 nm .$$

5. The optical filter according to claim 4, further satisfying the following spectral characteristics (i-12) to (i-14):
(i-12) the T_{(0deg)UV50} is in a wavelength range of 400 nm to 430 nm
(i-13) in a spectral transmittance curve at an incident angle of 50 degrees, a minimum wavelength T_{(50deg)UV50} at which a transmittance is 50% in a wavelength range of 350 nm to 430 nm is in a wavelength range of 400 nm to 430 nm
(i-14) an absolute value of a difference between the T_{(0deg)UV50} and the T_{(50deg)UV50} is 4 nm or less.

6. The optical filter according to claim 1, further satisfying the following spectral characteristic (i-15):
(i-15) the average transmittance T_{430-600(0deg)AVE} at a wavelength of 430 nm to 600 nm in a spectral transmittance curve at an incident angle of 0 degrees and an average transmittance T_{430-600(50deg)AVE} at a wavelength of 430 nm to 600 nm in a spectral transmittance curve at an incident angle of 50 degrees satisfy the following relation:
$${T}_{430 - 600 ( 0 dcg ) AVE} - {T}_{430 - 600 ( 50 dcg ) AVE} \leq 4.5 \% .$$

7. The optical filter according to claim 1, further satisfying the following spectral characteristics (i-16) and (i-17):
(i-16) when an antireflection layer 1 side is set as an incident direction, an average reflectance R1_{750-1100(5deg)AVE} at a wavelength of 750 nm to 1,100 nm in a spectral reflectance curve at an incident angle of 5 degrees is 15% or less
(i-17) when an antireflection layer 2 side is set as an incident direction, an average reflectance R2_{750-1100(5deg)AVE} at a wavelength of 750 nm to 1,100 nm in a spectral reflectance curve at an incident angle of 5 degrees is 15% or less.

8. The optical filter according to claim 1, wherein the UV dye comprises a merocyanine compound having a maximum absorption wavelength in a wavelength range of 370 nm to 410 nm in the resin.

9. The optical filter according to claim 8, wherein the UV dye comprises the merocyanine compound represented by the following formula (M): 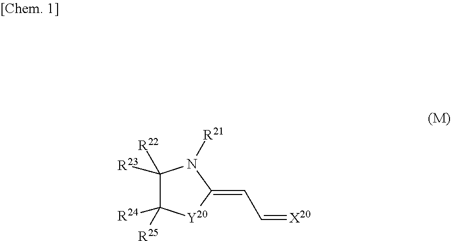
wherein definitions of symbols in the formula (M) are as follows:
R²¹ represents a monovalent hydrocarbon group having 1 to 16 carbon atoms which may have a substituent,
R²² to R²⁵ each independently represent a hydrogen atom, a halogen atom, an alkyl group having 1 to 10 carbon atoms, or an alkoxy group having 1 to 10 carbon atoms,
Y²⁰ represents a methylene group substituted with R²⁶ and R²⁷ or an oxygen atom, and
X²⁰ represents any of divalent groups represented by the following formulae (X1) to (X5): 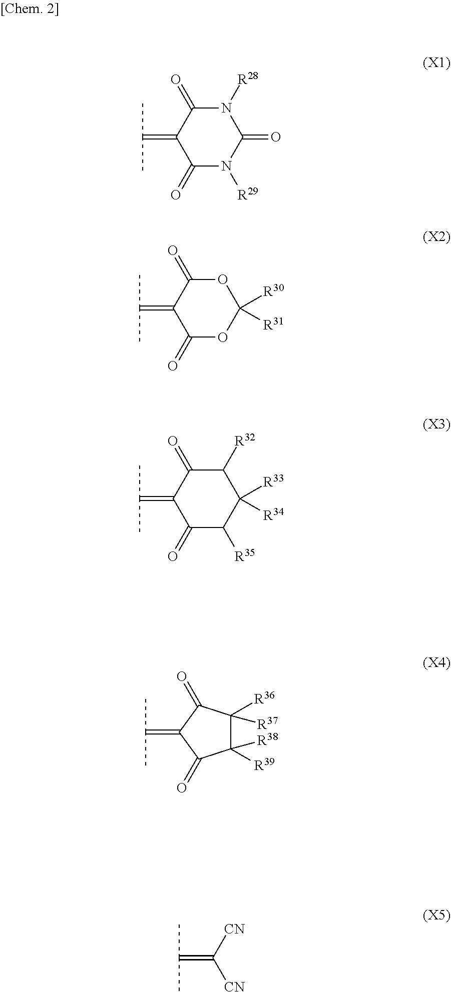
wherein R²⁸ and R²⁹ each independently represent a monovalent hydrocarbon group having 1 to 12 carbon atoms which may have a substituent, and R³⁰ to R³⁹ each independently represent a hydrogen atom or a monovalent hydrocarbon group having 1 to 12 carbon atoms which may have a substituent.

10. The optical filter according to claim 1, wherein the UV dye comprises a zeromethine compound having a maximum absorption wavelength in a wavelength range of 350 nm to 380 nm in the resin.

11. The optical filter according to claim 10, wherein the UV dye comprises the zeromethine compound represented by the following formula (I): 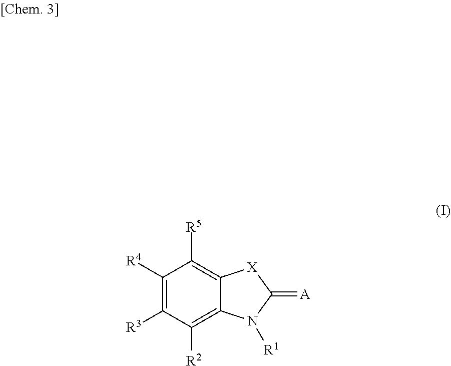
wherein definitions of symbols in the formula (I) are as follows:
X represents an oxygen atom, a sulfur atom, N—R¹⁴, or C—R¹⁵R¹⁶, wherein R¹⁴ to R¹⁶ each independently represent a hydrogen atom or an alkyl group having 1 to 10 carbon atoms which may have a substituent,
R¹ represents an alkyl group having 1 to 6 carbon atoms which may have a substituent,
R² to R⁵ each independently represent a hydrogen atom, a halogen atom, an alkyl group having 1 to 10 carbon atoms which may have a substituent, an alkoxy group having 1 to 10 carbon atoms which may have a substituent, a nitro group, an amino group, or an amide group, and
A represents any of divalent groups represented by the following formulae (A1) to (A4): 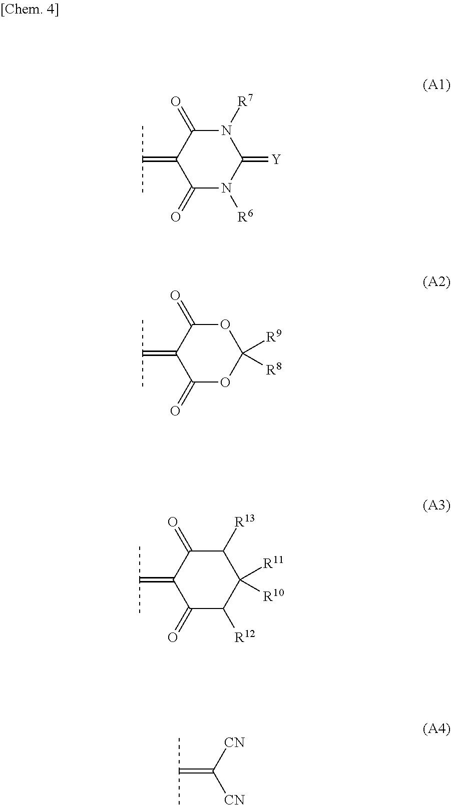
wherein in the formulae (A1) to (A4), Y represents an oxygen atom or a sulfur atom, and R⁶ to R¹³ each independently represent a hydrogen atom or an alkyl group having 1 to 10 carbon atoms which may have a substituent.

12. The optical filter according to claim 1, wherein each of the antireflection layer 1 and the antireflection layer 2 has a thickness of 1 μm or less.

13. The optical filter according to claim 1, wherein the number of layers of each of the antireflection layer 1 and the antireflection layer 2 is 20 or less.

14. The optical filter according to claim 1, wherein the near-infrared ray absorbing glass satisfies the following spectral characteristics (ii-1) and (ii-2):
(ii-1) an average internal transmittance T_{450-600AVE} at a wavelength of 450 nm to 600 nm is 80% or more
(ii-2) an average internal transmittance T_{750-1100AVE} at a wavelength of 750 nm to 1,100 nm is 5% or less.

15. The optical filter according to claim 1, wherein the near-infrared ray absorbing glass is a phosphate glass or a fluorophosphate glass comprising copper ions.

16. The optical filter according to claim 1, wherein the resin film has a thickness of 5 μm or less.

17. An imaging device comprising the optical filter according to claim 1.
